(19) United States
(12) Patent Application Publication
(10) Pub. No.: US 2023/0063990 A1
(43) Pub. Date: Mar. 2, 2023

(54) SEMICONDUCTOR APPARATUS, SOCKET, AND ELECTRONIC APPARATUS

(71) Applicant: FUJITSU LIMITED, Kawasaki-shi (JP)

(72) Inventor: Tsuyoshi So, Kawasaki (JP)

(73) Assignee: FUJITSU LIMITED, Kawasaki-shi (JP)

(21) Appl. No.: 17/747,311

(22) Filed: May 18, 2022

(30) Foreign Application Priority Data
Aug. 25, 2021 (JP) 2021-137337

(51) Int. Cl. H01L 23/40; H01R 12/70

(52) U.S. Cl. CPC H01L 23/4006; H01R 12/7076; H01L 2023/4087

(57) ABSTRACT

A semiconductor apparatus includes a semiconductor device configured to include a first pad, and a socket provided over a first pad side of the semiconductor device, and configured to include, a base configured to face the semiconductor device, a first terminal provided over a semiconductor device side of the base, configured to include flexibility against a load in a direction from the semiconductor device toward the base, and coupled to the first pad, a first tubular barrier provided over the semiconductor device side and configured to surround the first terminal, and a first elastic body provided over the semiconductor device side, and configured to support the first tubular barrier and energize the first tubular barrier in a direction from the base toward the semiconductor device.

### CROSS-REFERENCE TO RELATED APPLICATION

This application is based upon and claims the benefit of priority of the prior Japanese Patent Application No. 2021-137337, filed on Aug. 25, 2021, the entire contents of which are incorporated herein by reference.

### FIELD

The embodiments discussed herein are related to a semiconductor apparatus, a socket, and an electronic apparatus.

### BACKGROUND

There is known a coaxial pin in which two coaxial and independently axially movable conductive contact terminals are each supported by an elastic member and arranged in a hollow portion of a conductive terminal member, one of which is axially moved by a contact object and then another one of which contacts the contact object. There is known a technology in which such a coaxial pin is housed in a base member to form a socket, two contact terminals of the coaxial pin are brought into contact with a terminal region (contact object) of a semiconductor apparatus mounted on the base member, and the terminal region of the semiconductor apparatus is electrically and thermally coupled to the coaxial pin. Moreover, there is also known a technology in which a protrusion is formed on a surface of one of contact terminals of a coaxial pin in order to break through an insulating film formed on a surface of a contact object such as a terminal region of a semiconductor apparatus.

Furthermore, there is known a technology in which a circuit board and a die package are electrically connected via a socket assembly. In relation to such a socket assembly, there is known a technology in which, in an opening penetrating a socket substrate (socket housing), an electrical contactor having a bending contact portion such as a cantilever portion that routes an electrical signal between both surfaces of the socket substrate and extends beyond one surface is arranged. Moreover, there are known a technology in which a cover having an opening formed for housing a contact portion of an electrical contactor on a socket substrate, and a technology in which a spring structure is arranged between a socket substrate and a cover at corners or the like of a socket assembly. There is known a technology in which a die package is arranged on such a cover by applying a compressive force to form a contact between a contact portion of an electrical contactor and a corresponding contactor on the die package.

Japanese Laid-open Patent Publication No. 2014-146504 and International Publication Pamphlet No. WO 2016/048352 are disclosed as related art.

### SUMMARY

According to an aspect of the embodiments, a semiconductor apparatus includes a semiconductor device configured to include a first pad, and a socket provided over a first pad side of the semiconductor device, and configured to include, a base configured to face the semiconductor device, a first terminal provided over a semiconductor device side of the base, configured to include flexibility against a load in a direction from the semiconductor device toward the base, and coupled to the first pad, a first tubular barrier provided over the semiconductor device side and configured to surround the first terminal, and a first elastic body provided over the semiconductor device side, and configured to support the first tubular barrier and energize the first tubular barrier in a direction from the base toward the semiconductor device.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a view illustrating an example of a semiconductor apparatus;

FIG. 2 is a view illustrating an example of connection between a semiconductor device and a socket;

FIG. 3 is a view illustrating another example of the connection between the semiconductor device and the socket;

FIG. 4 is a view illustrating an example of a semiconductor apparatus according to a first embodiment;

FIG. 5 is a view (part 1) illustrating connection between a semiconductor device and a socket according to the first embodiment;

FIGS. 6A and 6B are views (part 2) illustrating the connection between the semiconductor device and the socket according to the first embodiment;

FIGS. 7A and 7B are views (part 3) illustrating the connection between the semiconductor device and the socket according to the first embodiment;

FIGS. 8A and 8B are views (part 4) illustrating the connection between the semiconductor device and the socket according to the first embodiment;

FIGS. 9A and 9B are views (part 5) illustrating the connection between the semiconductor device and the socket according to the first embodiment;

FIGS. 10A and 10B are views illustrating a configuration example of the semiconductor device according to the first embodiment;

FIGS. 11A and 11B are views (part 1) illustrating a configuration example of the socket according to the first embodiment;

FIG. 12 is a view (part 2) illustrating the configuration example of the socket according to the first embodiment;

FIGS. 13A and 13B are views illustrating a modification of the socket according to the first embodiment;

FIG. 14 is a view illustrating a configuration example of the semiconductor apparatus according to the first embodiment;

FIGS. 15A and 15B are views illustrating a first example of a socket according to a second embodiment;

FIGS. 16A and 16B are views illustrating a second example of the socket according to the second embodiment;

FIG. 17 is a view (part 1) illustrating an example of a socket according to a third embodiment;

FIG. 18 is a view (part 2) illustrating an example of the socket according to the third embodiment;

FIG. 19 is a view illustrating a configuration example of a semiconductor apparatus according to the third embodiment;

FIG. 20 is a view illustrating a modification of the socket according to the third embodiment;

FIG. 21 is a view illustrating an example of a semiconductor apparatus according to a fourth embodiment;

FIG. 22 is a view illustrating an example of a semiconductor apparatus according to a fifth embodiment; and

FIG. 23 is a view illustrating an example of an electronic apparatus according to a sixth embodiment.

### DESCRIPTION OF EMBODIMENTS

For a terminal portion of a socket connected to a pad of a semiconductor chip, a semiconductor package, or the like (hereinafter also referred to as “semiconductor device”), for example, one having flexibility against a load applied from a side of the semiconductor device to a side of the socket is used. The pad of the semiconductor device is pressed against such a terminal portion having flexibility by the load, and the socket and the semiconductor device are electrically connected.

Incidentally, warpage may occur in the semiconductor device. When warpage occurs in the semiconductor device, there are portions where a gap between the semiconductor device and the socket is different. In this case, when a load is applied, the pad of the semiconductor device and the terminal portion of the socket are connected in a portion where the gap is relatively small, while the pad of the semiconductor device and the terminal portion of the socket may not be connected In a portion where the gap is relatively large. It is also conceivable to lengthen the terminal portion of the socket in order to avoid disconnection between the pad of the semiconductor device and the terminal portion of the socket in the portion where the gap is relatively large. However, when the terminal portion of the socket is lengthened, there is a possibility that, at a portion where the gap is relatively small, the terminal portion is bent greatly, extends by elastic force of the terminal portion, and disengages from the pad of the semiconductor device, or a portion of an excess length is connected to a pad adjacent to the pad and causes a short circuit. Such a connection failure between the semiconductor device and the socket, such as disconnection or a short circuit between the pad and the terminal portion, results in deterioration of quality of the semiconductor apparatus including the semiconductor device and the socket.

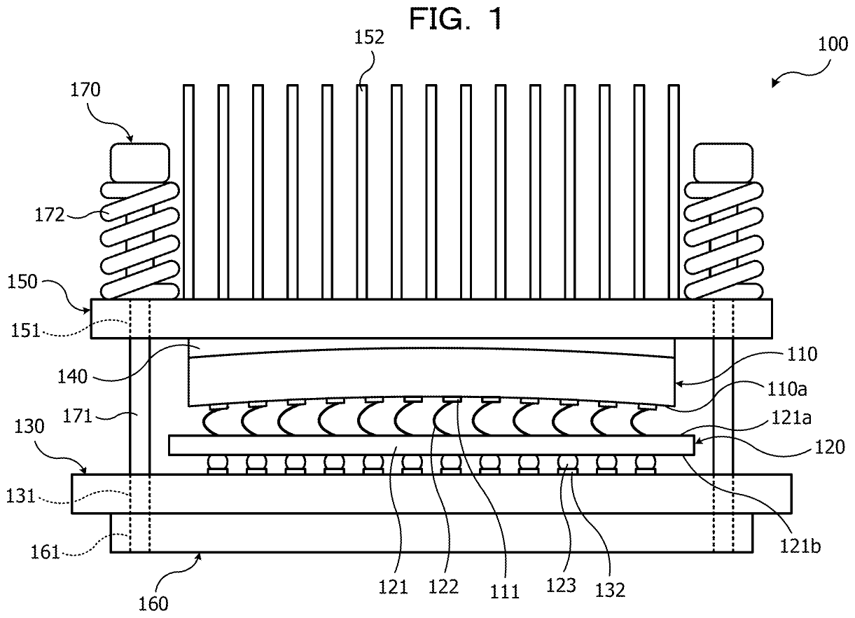

First, an example of the semiconductor apparatus will be described. FIG. 1 is a view illustrating an example of the semiconductor apparatus. In FIG. 1, a side view of a main part of an example of the semiconductor apparatus is schematically illustrated.

A semiconductor apparatus 100 illustrated in FIG. 1 includes a semiconductor device 110 and a socket 120. The semiconductor apparatus 100 further includes a substrate 130, a thermal bonding material 140, a cooling part 150, a plate 160, and fixing parts 170.

For the semiconductor device 110, for example, a semiconductor package is used. The semiconductor package includes, for example, a circuit board, a semiconductor chip mounted on the circuit board, and a sealing body for sealing the semiconductor chip. For the circuit board, a printed circuit board, an interposer, or the like is used. For the semiconductor chip, a semiconductor material such as silicon (Si), silicon carbide (SiC), or gallium nitride (GaN) is used, and a circuit device such as a transistor is formed on such a semiconductor material. For the sealing body, a resin material such as an epoxy resin, such a resin material containing a particulate or fibrous insulating filler, or the like is used. The semiconductor device 110 includes a plurality of pads 111 provided on a side of one surface 110a and electrically connected to the internal circuit device. Note that, for the semiconductor device 110, a semiconductor chip may be used in addition to the semiconductor package.

The socket 120 is provided on a side of the plurality of pads 111 of the semiconductor device 110. The socket 120 includes a base portion 121, a plurality of terminal portions 122, and a plurality of bumps 123. For the base portion 121, a resin material such as an epoxy resin is used. For the plurality of terminal portions 122, a metal material such as copper (Cu) or Cu alloy is used. The plurality of terminal portions 122 is provided on a side of one surface 121a of the base portion 121 (the side of the surface 121a facing the semiconductor device 110). The plurality of terminal portions 122 is provided at positions corresponding to the plurality of pads 111 of the semiconductor device 110. The plurality of terminal portions 122 has flexibility against a load in a direction from the semiconductor device 110 toward the base portion 121. The plurality of terminal portions 122 is erected on the base portion 121 so as to have such flexibility. For the plurality of bumps 123, a solder material such as tin (Sn)-based solder is used. The plurality of bumps 123 is provided on a side of another surface 121b of the base portion 121 (the side of the surface 121b opposite to the side of the surface 121a facing the semiconductor device 110). Although illustration is omitted in FIG. 1, for the plurality of terminal portions 122 and the plurality of bumps 123, for example, ones corresponding to each other are electrically connected to each other through conductor portions provided so as to make conduction between the surface 121a and the surface 121b of the base portion 121.

The substrate 130 is provided on a side of the plurality of bumps 123 of the socket 120. For the substrate 130, a circuit board such as a printed circuit board is used. The plurality of bumps 123 of the socket 120 is bonded to a plurality of pads 132 provided on the substrate 130 by reflow or the like. The substrate 130 is provided with through holes 131 into which the fixing parts 170 are inserted, outside a region facing the semiconductor device 110 and the socket 120, for example, at ends such as four corners of the substrate 130.

The thermal bonding material 140 is provided on a side of the semiconductor device 110 opposite to the side of the plurality of pads 111. For the thermal bonding material 140, various thermal interface materials (TIMs) such as a heat conductive sheet and a heat conductive paste are used.

The cooling part 150 is provided on a side of the thermal bonding material 140 opposite to a side of the semiconductor device 110. For the cooling part 150, a metal material such as Cu, Cu alloy, aluminum (Al), or Al alloy is used. The cooling part 150 is provided with fins 152 having various shapes such as a plate shape and a needle shape in order to increase a surface area and enhance cooling efficiency. The cooling part 150 is provided with through holes 151 into which the fixing parts 170 are inserted at portions corresponding to the through holes 131 of the substrate 130 outside the region facing the semiconductor device 110 and the socket 120, for example, at ends such as four corners of the cooling part 150. Note that, for the cooling part 150, for example, one provided with a flow path for circulating a liquid or gas refrigerant in a block of a metal material or the like may be used.

The plate 160 is provided on a side of the substrate 130 opposite to a side of the socket 120. For the plate 160, a material having relatively high rigidity such as metal is used. The plate 160 is provided with screw holes 161 into which tip portions of the fixing parts 170 are screwed at portions corresponding to the through holes 151 of the cooling part 150 and the through holes 131 of the substrate 130, for example, ends such as four corners of the plate 160.

For the fixing part 170, a spring-loaded screw including a screw 171 provided with a screw thread at a tip portion and a spring 172 into which the screw 171 is inserted is used. The screw 171 inserted into the spring 172 is inserted into the through hole 151 of the cooling part 150 and the through hole 131 of the substrate 130, and the tip portion of the screw 171 is screwed into the screw hole 161 of the plate 160. The spring 172 is sandwiched between a head of the screw 171 and the cooling part 150 to energize the cooling part 150 toward a side of the plate 160.

In the semiconductor apparatus 100, a screwing amount of the fixing parts 170 relative to the plate 160 is adjusted within an appropriate range, and the thermal bonding material 140, the semiconductor device 110, the socket 120, and the substrate 130 are sandwiched between the cooling part 150 and the plate 160. At this time, the semiconductor device 110 is brought close to the socket 120 as the screwing amount of the fixing parts 170 increases, so that a load from the side of the semiconductor device 110 is applied to the socket 120. The plurality of terminal portions 122 of the socket 120 is connected to the corresponding plurality of pads 111 of the semiconductor device 110, and is bent by the load from the side of the semiconductor device 110.

The terminal portions 122 of the socket 120 are bent by the load from the side of the semiconductor device 110, and rub and wipe surfaces of the pads 111 of the semiconductor device 110 by elastic force generated by the bending. By this wiping, a coating film, dust, and the like existing on the surfaces of the pads 111 of the semiconductor device 110 are removed, and clean surfaces of the pads 111 and the terminal portions 122 of the socket 120 are connected. With this configuration, an increase in resistance between the pads 111 and the terminal portions 122 is suppressed.

Incidentally, for the semiconductor device 110 included in the semiconductor apparatus 100 described above, constituent materials having thermal expansion coefficients different from each other, such as Si, metal, and resin, are used. Therefore, when the semiconductor device 110 undergoes a thermal process such as reflow or baking in a formation process thereof or an assembly process of the semiconductor apparatus 100, warpage may occur due to a difference in the thermal expansion coefficient of each constituent material. In FIG. 1, as an example, the semiconductor apparatus 100 including such a semiconductor device 110 in a state where warpage occurs is illustrated.

In recent years, as an electronic apparatus on which the semiconductor apparatus 100 is mounted has become more sophisticated, the semiconductor device 110 has become more sophisticated, and a size of the semiconductor device 110 tends to enlarge. As the size of the semiconductor device 110 enlarges, warpage that occurs in the semiconductor device 110 is also likely to enlarge. Moreover, along with the sophistication, the plurality of pads 111 provided in the semiconductor device 110 are also increased in number and reduced in pitch.

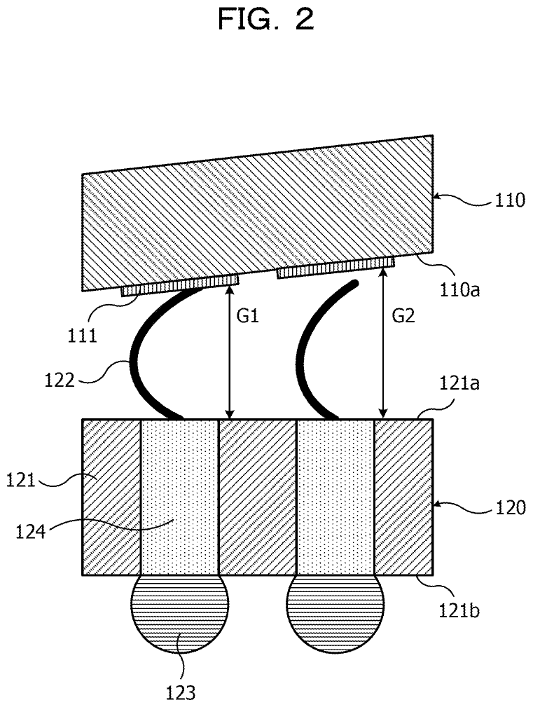

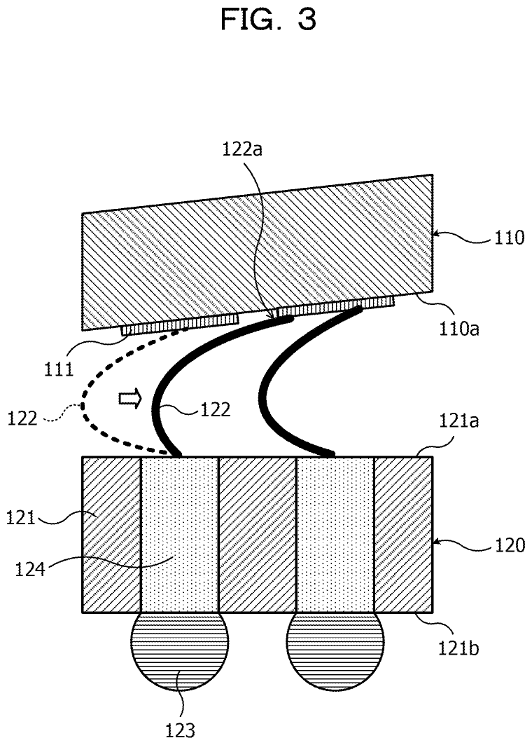

Even when warpage occurs in the semiconductor device 110, when the warpage is relatively small, the pads 111 and the terminal portions 122 may be connected by adjusting the screwing amount of the fixing parts 170 within the appropriate range and adjusting the load applied to the socket 120 to absorb influence of the warpage. However, when the warpage that occurs in the semiconductor device 110 is relatively large, even when the screwing amount of the fixing parts 170 is adjusted within the appropriate range and the load is adjusted, it is not possible to sufficiently absorb the influence of the warpage, and a connection failure between the pads 111 and the terminal portions 122 may occur. This point will be described with reference to the following FIGS. 2 and 3.

FIG. 2 is a view illustrating an example of connection between the semiconductor device and the socket. In FIG. 2, a cross-sectional view of a main part of the semiconductor device and the socket is schematically illustrated. The semiconductor device 110 is provided with the plurality of pads 111 on the one surface 110a, and the socket 120 is provided on the side of the plurality of pads 111 of the semiconductor device 110. The socket 120 is provided with the plurality of terminal portions 122 having flexibility on the side of the surface 121a of the base portion 121 facing the plurality of pads 111 of the semiconductor device 110, and is provided with the plurality of bumps 123 on the side of the opposite surface 121b. For the plurality of terminal portions 122 and the plurality of bumps 123, ones corresponding to each other are electrically connected to each other through conductor portions 124 provided so as to make conduction between the surface 121a and the surface 121b of the base portion 121.

When warpage occurs in the semiconductor device 110, some of the plurality of pads 111 provided on the surface 110a of the semiconductor device 110 have different gaps from the base portion 121 of the socket 120. For example, as illustrated in FIG. 2, among the plurality of pads 111 of the semiconductor device 110, there are a pad 111 having a gap G1 and a pad 111 having a gap G2 larger than the gap G1. When the warpage that occurs in the semiconductor device 110 is relatively large and a difference between the gap G1 and the gap G2 is large, the following may occur even when the screwing amount of the fixing parts 170 is adjusted within the appropriate range and the load is adjusted. For example, as illustrated in FIG. 2, the pad 111 at a portion having the relatively small gap G1 of the semiconductor device 110 may be connected to a corresponding terminal portion 122, while the pad 111 at a portion having the relatively large gap G2 of the semiconductor device 110 may not be connected to a corresponding terminal portion 122.

FIG. 3 is a view illustrating another example of the connection between the semiconductor device and the socket. In FIG. 3, a cross-sectional view of the main part of the semiconductor device and the socket is schematically illustrated. In order to avoid disconnection between the pad 111 and the terminal portion 122 as illustrated in FIG. 2 described above, it is conceivable to lengthen lengths of the plurality of terminal portions 122 of the socket 120 as illustrated in FIG. 3 on the basis of the relatively larger gap G2 of the gap G1 and the gap G2. For example, it is conceivable to lengthen the lengths of the plurality of terminal portions 122 of the socket 120 so that connection to the corresponding pads 111 is possible even when the gap is relatively large.

However, when the lengths of the plurality of terminal portions 122 of the socket 120 are lengthened in this way, the following may occur. For example, as illustrated in FIG. 3, the terminal portion 122 at the portion having the relatively small gap may have great bending due to its lengthened length. There is a possibility that, by elastic force of the terminal portion 122 that is greatly bent, a tip portion 122a of the terminal portion 122 slips on the surface of the pad 111 and disengages from the pad 111. Furthermore, there is a possibility that a portion of the terminal portion 122 that is greatly bent, which is disengaged from the pad 111, or the portion of an excess length after being connected to the pad 111, may be connected to a pad 111 adjacent to the pad 111, causing a short circuit. As the plurality of pads 111 provided in the semiconductor device 110 are reduced in pitch, such a short circuit with the adjacent pad 111 is more likely to occur.

In this way, in the socket 120 as described above, there is a possibility that disconnection or a short circuit occurs between the terminal portions 122 of the socket 120 and the pads 111 of the semiconductor device 110, which results in a connection failure between the socket 120 and the semiconductor device 110. The greater the warpage that occurs in the semiconductor device 110, the more likely it is that such disconnection or a short circuit between the pads 111 of the semiconductor device 110 and the terminal portions 122 of the socket 120 will occur. The connection failure between the semiconductor device 110 and the socket 120 results in deterioration of quality of the semiconductor apparatus 100 including the semiconductor device 110 and the socket 120.

In view of the points described above, here, methods indicated as embodiments below are used to suppress the connection failure between the semiconductor device and the socket and achieve a high-quality semiconductor apparatus.

### First Embodiment

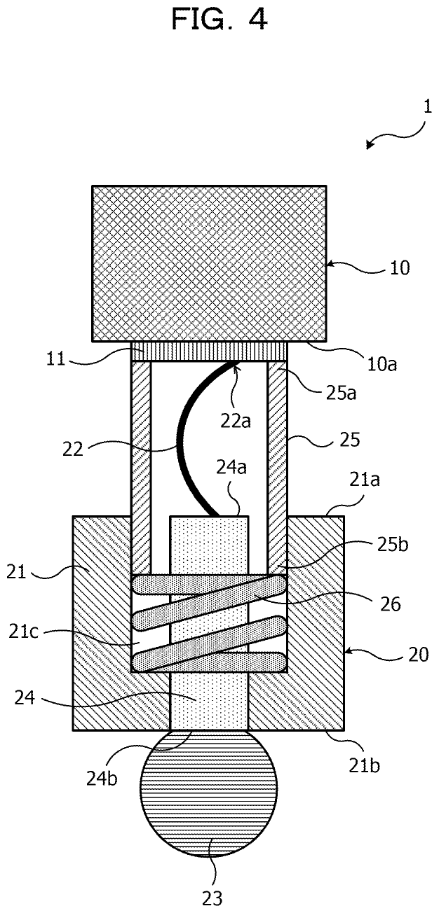

FIG. 4 is a view illustrating an example of a semiconductor apparatus according to a first embodiment. In FIG. 4, a cross-sectional view of a main part of an example of the semiconductor apparatus according to the first embodiment is schematically illustrated.

A semiconductor apparatus 1 illustrated in FIG. 4 includes a semiconductor device 10 and a socket 20. In the semiconductor apparatus 1, for example, a load is applied to the socket 20 from a side of the semiconductor device 10. For the semiconductor device 10, for example, a semiconductor package is used. The semiconductor package includes, for example, a circuit board, a semiconductor chip mounted on the circuit board, and a sealing body for sealing the semiconductor chip. For the circuit board, a printed circuit board, an interposer, or the like is used. For the semiconductor chip, a semiconductor material such as Si, SiC, or GaN is used, and a circuit device such as a transistor is formed on such a semiconductor material. For the sealing body, a resin material such as an epoxy resin, such a resin material containing a particulate or fibrous insulating filler, or the like is used. The semiconductor device 10 includes a pad 11 provided on a side of one surface 10a and electrically connected to the internal circuit device. Note that, for the semiconductor device 10, a semiconductor chip may be used in addition to the semiconductor package.

The socket 20 is provided on a side of the pad 11 of the semiconductor device 10. The socket 20 includes a base portion 21, a terminal portion 22, and a bump 23. The socket 20 further includes a conductor portion 24, a barrier portion 25, and an elastic portion 26.

For the base portion 21, a resin material such as an epoxy resin, a phenol resin, an acrylonitrile-butadiene-styrene (ABS) resin, a polyimide (PI) resin, or a polyphenylene sulfide (PPS) resin is used. The base portion 21 is provided with, for example, a recess 21c recessed from a side of one surface 21a toward a side of another surface 21b at a position facing the pad 11 of the semiconductor device 10.

For the terminal portion 22, a metal material such as Cu, Cu alloy, Al, or Al alloy is used. The terminal portion 22 is provided on the side of the surface 21a of the base portion 21 facing the semiconductor device 10. The terminal portion 22 is provided at a position corresponding to the pad 11 of the semiconductor device 10. The terminal portion 22 is connected to the pad 11 of the semiconductor device 10. The terminal portion 22 has flexibility against a load in the direction from the semiconductor device 10 toward the base portion 21. For the terminal portion 22, a member such as a leaf spring or a wire spring having a spring property is used. The terminal portion 22 is pushed by the pad 11 by the load in the direction from the semiconductor device 10 toward the base portion 21, and is connected to the pad 11 in a bent state.

For the bump 23, a solder material such as Sn-based solder is used. The bump 23 is provided on the side of the surface 21b of the base portion 21 opposite to the side of the surface 21a facing the semiconductor device 10.

The conductor portion 24 is provided in the recess 21c of the base portion 21 so as to penetrate a bottom portion of the recess 21c. The conductor portion 24 is fixed to the base portion 21. For the conductor portion 24, a metal material such as Cu, Cu alloy, Al, or Al alloy is used. For the conductor portion 24, a columnar member, for example, a cylindrical member is used. A thickness (height) of the conductor portion 24 may be set to be, for example, the same as a thickness of the base portion 21 from the surface 21b to the surface 21a. Note that the thickness of the conductor portion 24 is not limited to this, and may be thicker or thinner than the thickness of the base portion 21 from the surface 21b to the surface 21a. An end surface 24a of the conductor portion 24 on the side of the surface 21a of the base portion 21 may be positioned at a position protruding outward from the surface 21a or at a position not protruding from the surface 21a. An end surface 24b on the side of the surface 21b of the base portion 21 may be positioned at a position protruding outward from the surface 21b. The base portion 21 provided with the conductor portion 24 is formed by, for example, insert molding.

The terminal portion 22 is connected to the end surface 24a of the conductor portion 24 on the side of the surface 21a of the base portion 21. The conductor portion 24 has a function as a support portion that supports the terminal portion 22. The terminal portion 22 is connected to and fixed to the end surface 24a of the conductor portion 24 by using a method such as bonding or welding using a material such as solder or wax. The terminal portion 22 is erected on the end surface 24a of the conductor portion 24 so as to have flexibility against the load in the direction from the semiconductor device 10 toward the base portion 21. Furthermore, the bump 23 is connected to and fixed to the end surface 24b of the conductor portion 24 on the side of the surface 21b of the base portion 21. The terminal portion 22 and the bump 23 are electrically connected to each other through the conductor portion 24 provided in the base portion 21.

The barrier portion 25 is provided on the side of the surface 21a of the base portion 21 facing the semiconductor device 10 (the side opposite to the surface 21b of the base portion 21). The barrier portion 25 is provided at a position corresponding to the pad 11 of the semiconductor device 10. For the barrier portion 25, a tubular member, for example, a cylindrical member is used. The barrier portion 25 is provided so as to surround the terminal portion 22 and the conductor portion 24 (a part thereof) in a wall shape. The barrier portion 25 is provided so that a part on a side of an end 25b thereof is positioned in the recess 21c of the base portion 21. For the barrier portion 25, for example, an insulating material such as a resin material or a ceramic material is used. In addition, for the barrier portion 25, a conductive material such as a metal material may be used.

The elastic portion 26 is provided on the side of the surface 21a of the base portion 21 facing the semiconductor device 10 (the side opposite to the surface 21b of the base portion 21). The elastic portion 26 is provided at a position corresponding to the pad 11 of the semiconductor device 10. For the elastic portion 26, a member having a spring property, for example, a coil spring is used. For example, a coil spring as the elastic portion 26 is provided in the recess 21c of the base portion 21 so that the conductor portion 24 is inserted into a central portion of the coil spring. The elastic portion 26 has an energizing force in a direction from the base portion 21 toward the semiconductor device 10 provided on the side of the surface 21a of the base portion 21.

The one end 25b of the barrier portion 25 is connected to and fixed to one end of the elastic portion 26. Another end of the elastic portion 26 is connected to and fixed to the base portion 21. For example, an adhesive is used to connect the elastic portion 26 to the barrier portion 25 and the base portion 21. The end 25b of the barrier portion 25 is supported by the elastic portion 26 on the base portion 21, and the barrier portion 25 is energized by the elastic portion 26 in the direction from the base portion 21 toward the semiconductor device 10. In the barrier portion 25 energized by the elastic portion 26 from the side of the one end 25b, another end 25a is in contact with the semiconductor device 10 (as an example, the pad 11 thereof) and is connected to the semiconductor device 10. An inner wall of the recess 21c of the base portion 21 may be provided with a function of guiding displacement of the barrier portion 25 energized by the elastic portion 26 in this way.

Note that FIG. 4 illustrates, in a cross-sectional view, an example in which the end 25a of the barrier portion 25 energized by the elastic portion 26 is connected to the pad 11 of the semiconductor device 10, but the portion to which the end 25a of the barrier portion 25 is connected is not limited to this. The end 25a of the barrier portion 25 energized by the elastic portion 26 may be connected to a portion outside the pad 11 (the surface 10a in the example of FIG. 4) in addition to the pad 11 of the semiconductor device 10.

Furthermore, a gap may be partially formed between the semiconductor device 10 and the end 25a of the barrier portion 25 connected to the semiconductor device 10 as long as the gap is less than a thickness of a tip portion 22a of the terminal portion 22. For example, in a case where warpage occurs in the semiconductor device 10 and the semiconductor device 10 (the surface 10a or the pad 11 thereof) is inclined relative to the surface 21a of the base portion 21, a gap may be partially formed between the semiconductor device 10 and the end 25a of the barrier portion 25. Such a gap may be formed as long as the gap is less than the thickness of the tip portion 22a of the terminal portion 22.

In the semiconductor apparatus 1 having the configuration described above, by application of the load in the direction from the semiconductor device 10 to the socket 20, the terminal portion 22 is connected to the pad 11, and the barrier portion 25 surrounding the terminal portion 22 is energized toward the side of the semiconductor device 10 by the elastic portion 26 and connected to the semiconductor device 10. Since the terminal portion 22 is surrounded by the barrier portion 25 connected to the semiconductor device 10, it is avoided that the terminal portion 22 extends by elastic force generated by bending and disengages from the corresponding connected pad 11, and that the terminal portion 22 extends to and is connected to a pad (not illustrated) adjacent to the pad 11 and causes a short circuit. Even when the semiconductor device 10 is brought close to the socket 20, the barrier portion 25 is pushed toward a side of the base portion 21 against the energizing force of the elastic portion 26 while maintaining the state of being connected to the semiconductor device 10. Therefore, it is avoided by the elastic force of the terminal portion 22 that, even when the terminal portion 22 is greatly bent, the tip portion 22a slips on a surface of the pad 11 and extends to the outside of the barrier portion 25. With this configuration, it is avoided that the terminal portion 22 disengages from the corresponding connected pad 11 and that the terminal portion 22 is connected to a pad adjacent to the pad 11 and causes a short circuit. By using the socket 20 described above, the high-quality semiconductor apparatus 1 is achieved in which a connection failure between the semiconductor device 10 and the socket 20 is suppressed.

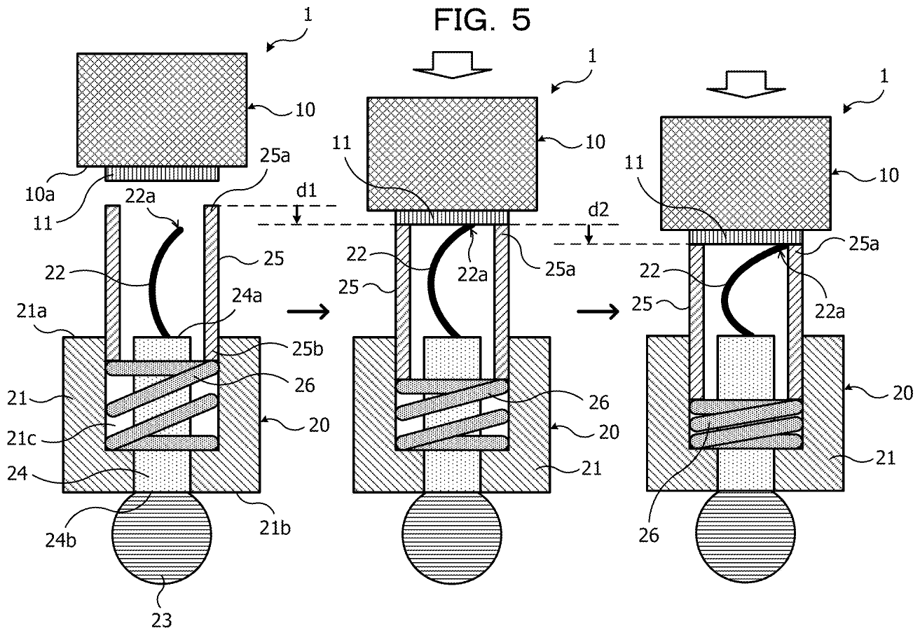

The connection between the semiconductor device 10 and the socket 20 will be described in more detail. FIGS. 5 and 6A to 9B are views illustrating the connection between the semiconductor device and the socket according to the first embodiment.

Here, in FIG. 5, a cross-sectional view of a main part of a connection process of the semiconductor device and the socket according to the first embodiment is schematically illustrated.

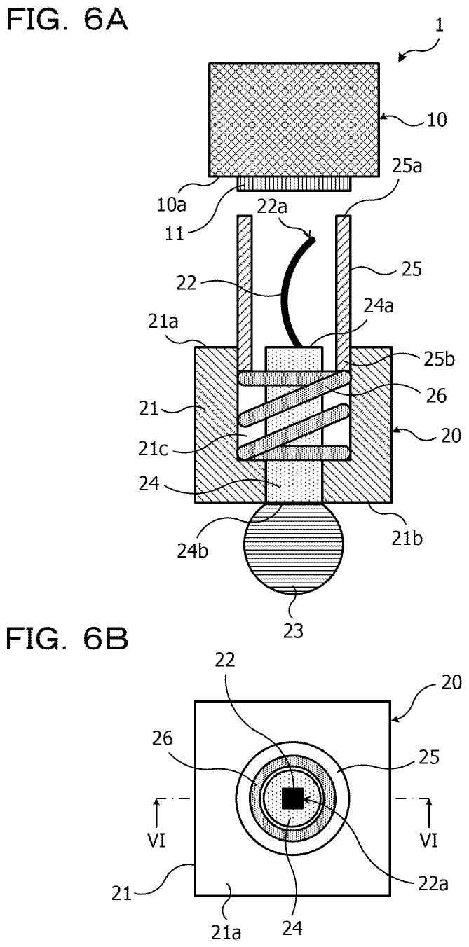

In FIG. 6A, a cross-sectional view of the main part of the semiconductor device and the socket according to the first embodiment in a no-load state is schematically illustrated, and in FIG. 6B, a plan view of the main part of the socket according to the first embodiment in the no-load state is schematically illustrated. Note that FIG. 6A is a view corresponding to a left view of FIG. 5, and a cross section of the socket in FIG. 6A corresponds to a VI-VI cross section of FIG. 6B.

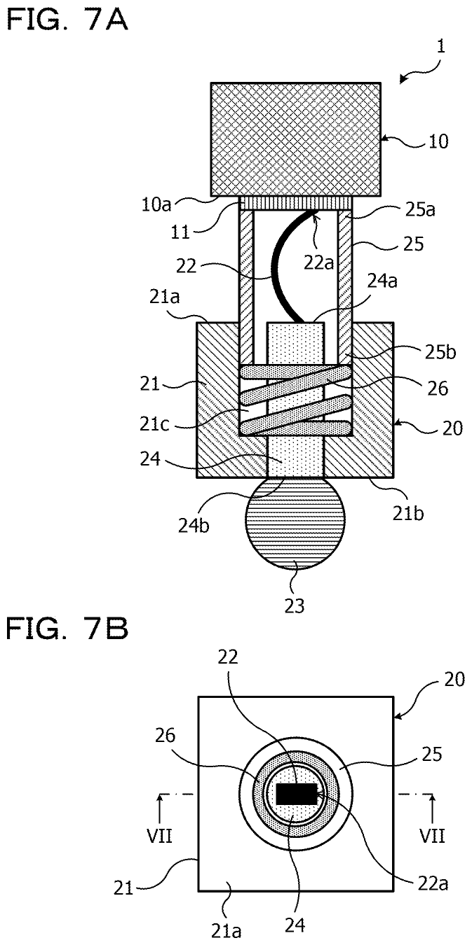

Furthermore, in FIG. 7A, a cross-sectional view of the main part of the semiconductor device and the socket according to the first embodiment in a first load state is schematically illustrated, and in FIG. 7B, a plan view of the main part of the socket according to the first embodiment in the first load state is schematically illustrated. Note that FIG. 7A is a view corresponding to a central view of FIG. 5, and a cross section of the socket in FIG. 7A corresponds to a VII-VII cross section of FIG. 7B.

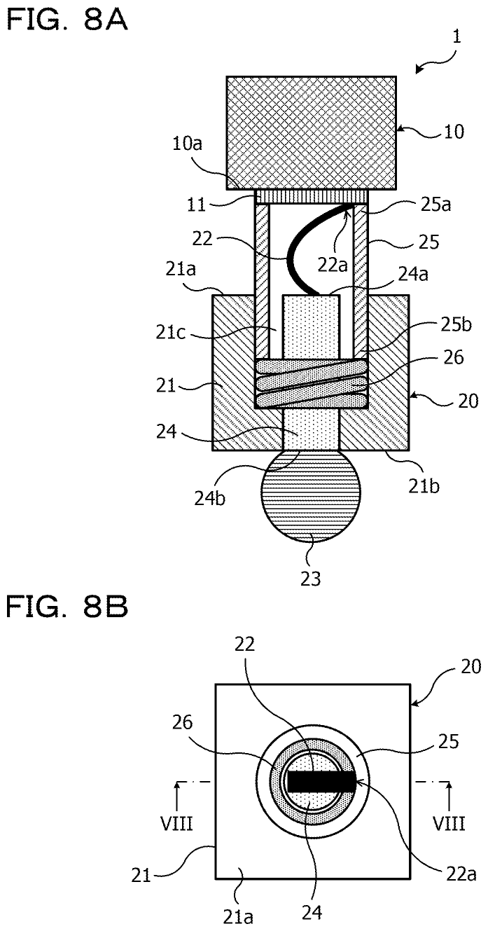

Furthermore, in FIG. 8A, a cross-sectional view of the main part of the semiconductor device and the socket according to the first embodiment in a second load state is schematically illustrated, and in FIG. 8B, a plan view of the main part of the socket according to the first embodiment in the second load state is schematically illustrated. Note that FIG. 8A is a view corresponding to a right view of FIG. 5, and a cross section of the socket in FIG. 8A corresponds to a VIII-VIII cross section of FIG. 8B.

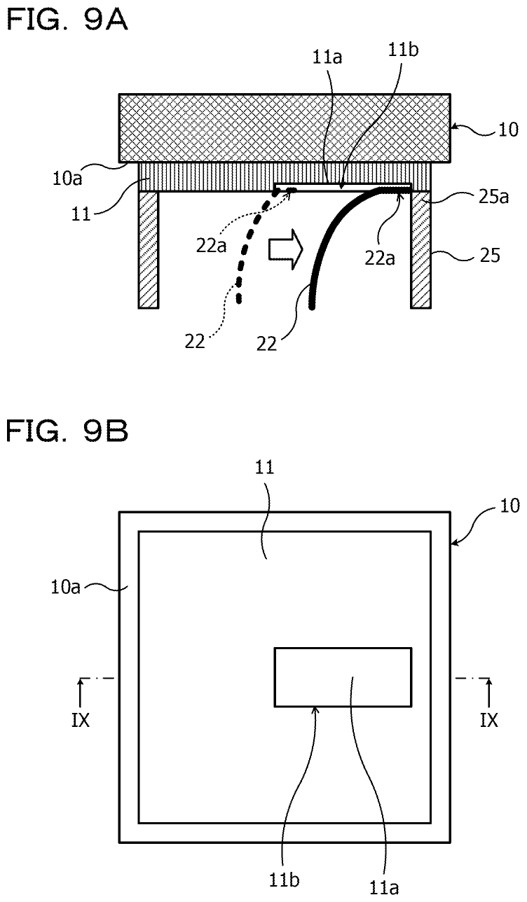

In FIG. 9A, an enlarged cross-sectional view of the main part of the semiconductor device and the socket according to the first embodiment in the second load state is schematically illustrated, and in FIG. 9B, an enlarged plan view of the main part of the semiconductor device according to the first embodiment in the second load state is schematically illustrated. Note that a cross section of the semiconductor device in FIG. 9A corresponds to a IX-IX cross section of FIG. 9B.

The connection between the semiconductor device 10 and the socket 20 will be described with reference to FIGS. 5 and 6A to 9B. As illustrated in the left view of FIG. 5 and FIGS. 6A and 6B, in the socket 20, the terminal portion 22 having flexibility is connected to the another end surface 24a of the conductor portion 24 which penetrates the base portion 21 and has the bump 23 connected to the one end surface 24b. The terminal portion 22 is surrounded by the tubular barrier portion 25 in a wall shape, and in the barrier portion 25, the one end 25b thereof is supported by the elastic portion 26. In the no-load state of the socket 20, as illustrated in the left view of FIG. 5 and FIG. 6A, the another end 25a of the barrier portion 25 having the one end 25b supported by the elastic portion 26 is positioned higher than the tip portion 22a of the terminal portion 22 relative to the surface 21a of the base portion 21. In the no-load state, a height (length) of the barrier portion 25 from the end 25b to the end 25a, a length of the terminal portion 22 from the conductor portion 24, a height (length) of the elastic portion 26 from one end to another end, and the like are adjusted so that the end 25a of the barrier portion 25 and the tip portion 22a of the terminal portion 22 have such a positional relationship.

When the semiconductor device 10 is brought close to the socket 20 in the no-load state, first, the semiconductor device 10 (in this example, the pad 11 thereof) is connected to the end 25a of the barrier portion 25 positioned higher than the tip portion 22a of the terminal portion 22. When the semiconductor device 10 is further brought close to the base portion 21, for example, as illustrated in the central view of FIG. 5 and FIG. 7A, the barrier portion 25 is pushed against the energizing force of the elastic portion 26. Then, when the end 25a of the barrier portion 25 is pushed to a height of the tip portion 22a of the terminal portion 22 in the no-load state, the tip portion 22a of the terminal portion 22 is connected to the pad 11 of the semiconductor device 10. From this state, when the semiconductor device 10 is further brought close to the base portion 21 and a load is applied to the socket 20, the barrier portion 25 is further pushed against the energizing force of the elastic portion 26 while maintaining the state where the end 25a of the barrier portion 25 is connected to the semiconductor device 10. At the same time, the tip portion 22a of the terminal portion 22 is pushed by the pad 11 of the semiconductor device 10, and, for example, as illustrated in the central view of FIG. 5 and FIGS. 7A and 7B, the terminal portion 22 is bent more than in the no-load state.

Note that the left view and the central view of FIG. 5 illustrates, as a state in the first load state, a state where the barrier portion 25 is pushed by the load from the side of the semiconductor device 10, and a position of the end 25a of the barrier portion 25 is displaced by a distance d1 from the no-load state.

When a load is further applied from the first load state and the semiconductor device 10 is further brought close to the base portion 21, for example, as illustrated in the right view of FIG. 5 and FIG. 8A, the barrier portion 25 is further pushed against the energizing force of the elastic portion 26. At the same time, the tip portion 22a of the terminal portion 22 is pushed by the pad 11 of the semiconductor device 10, and, for example, as illustrated in the right view of FIG. 5 and FIGS. 8A and 8B, the terminal portion 22 is further bent.

Note that the central view and the right view of FIG. 5 illustrates, as a state in the second load state, a state where the barrier portion 25 is further pushed by the load from the side of the semiconductor device 10, and the position of the end 25a of the barrier portion 25 is further displaced by a distance d2 from the first load state.

In the process of transitioning from the first load state to the second load state, as illustrated in FIG. 9A, the tip portion 22a of the terminal portion 22 moves toward an outer peripheral portion of the pad 11 while rubbing the surface of the pad 11 by the elastic force generated by the bending, and wipes the surface of the pad 11. Note that, in FIG. 9A, the terminal portion 22 before wiping is indicated by a dotted line, and the movement of the terminal portion 22 is indicated by a thick arrow. By this wiping, a coating film, dust, and the like existing on the surface of the pad 11 of the semiconductor device 10 are removed, and as illustrated in FIG. 9A, a clean surface 11a of the pad 11 is exposed. The terminal portion 22 is connected to the exposed clean surface 11a of the pad 11. With this configuration, an increase in resistance between the pad 11 and the terminal portion 22 is suppressed. As illustrated in FIG. 9B, on the surface of the pad 11 wiped by the terminal portion 22, a wiping trace 11b in which the clean surface 11a is exposed, is formed on a locus of the movement of the tip portion 22a of the terminal portion 22.

In this way, during the wiping, for example, in the process of transitioning from the first load state to the second load state, the tip portion 22a of the terminal portion 22 moves toward the outer peripheral portion of the pad 11 while rubbing the surface of the pad 11. In the socket 20, even when the tip portion 22a of the terminal portion 22 moves toward the outer peripheral portion of the pad 11 in this way, the state is maintained where the barrier portion 25 surrounding the terminal portion 22 is connected to the semiconductor device 10 by the energizing force of the elastic portion 26. For example, from the first load state as illustrated in the central view of FIG. 5 and FIG. 7A to the second load state as illustrated in the right view of FIG. 5 and FIGS. 8A and 9A, the barrier portion 25 surrounding the terminal portion 22 is connected to the semiconductor device 10 by the energizing force of the elastic portion 26.

Therefore, the tip portion 22a of the terminal portion 22, which moves toward the outer peripheral portion of the pad 11, may come into contact with an inner wall of the barrier portion 25, but is suppressed from extending to the outside of the barrier portion 25. With this configuration, it is avoided that the terminal portion 22 disengages from the pad 11 and that the terminal portion 22 extends to and is connected to a pad (not illustrated) adjacent to the pad and causes a short circuit. In this way, since the disengagement of the terminal portion 22 from the pad 11 and the short circuit with the adjacent pad are avoided, a sufficient load that may connect the terminal portion 22 to the pad 11 may be applied. Therefore, disconnection between the terminal portion 22 and the pad 11 due to an insufficient load is also avoided. By using the socket 20 described above, the high-quality semiconductor apparatus 1 is achieved in which a connection failure between the semiconductor device 10 and the socket 20 is suppressed.

Furthermore, as described above, for example, an insulating material such as a resin material or a ceramic material may be used for the barrier portion 25 of the socket 20. When such an insulating material is used for the barrier portion 25, in a case where the barrier portion 25 is connected to the pad 11, conduction therebetween is avoided. With this configuration, an electrical action of the barrier portion 25 on transmission of an electrical signal between the pad 11 and the terminal portion 22 is suppressed. In addition, in a case where the barrier portion 25 is connected to the outside of the pad 11 (surface 10a), the pad 11 is surrounded by the barrier portion 25. With this configuration, since the pad 11 is protected from the outside by the barrier portion 25, even when a conductive foreign substance enters between the adjacent pads 11, it is possible to suppress a short circuit between the adjacent pads 11 due to movement, diffusion, or the like of the foreign substance.

Furthermore, as described above, for example, a conductive material such as a metal material may be used for the barrier portion 25 of the socket 20. When such a conductive material is used for the barrier portion 25, both in a case where the barrier portion 25 is connected to the pad 11 and a case where the barrier portion 25 is connected to the outside of the pad 11, the barrier portion 25 connected to the semiconductor device 10 functions as one of heat dissipation paths for transmitting heat generated in the semiconductor device 10. With this configuration, heat dissipation efficiency of the semiconductor device 10 is enhanced.

Note that, when a material having an insulating property and high thermal conductivity is used for the barrier portion 25, it is possible to suppress the electrical action of the barrier portion 25 on the transmission of the electrical signal, suppress the short circuit between the adjacent pads 11, and improve the heat dissipation efficiency of the semiconductor device 10, as described above. Examples of the material having an insulating property and high thermal conductivity include a ceramic material such as SiC and aluminum nitride (AlN).

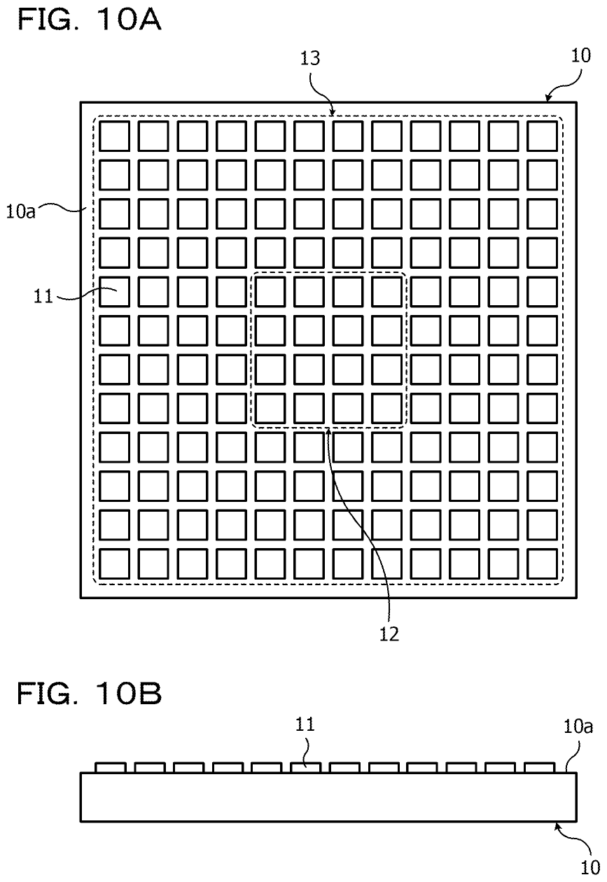

Subsequently, a configuration example of the semiconductor device 10 and the socket 20 will be described. FIGS. 10A and 10B are views illustrating the configuration example of the semiconductor device according to the first embodiment. In FIG. 10A, a plan view of a main part of the configuration example of the semiconductor device according to the first embodiment is schematically illustrated, and in FIG. 10B, a side view of the main part of the configuration example of the semiconductor device according to the first embodiment is schematically illustrated.

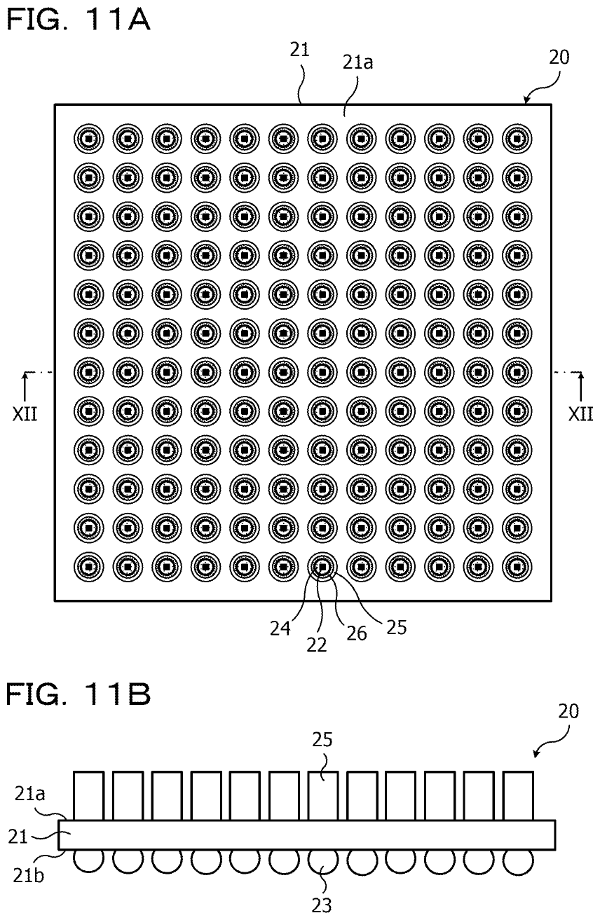

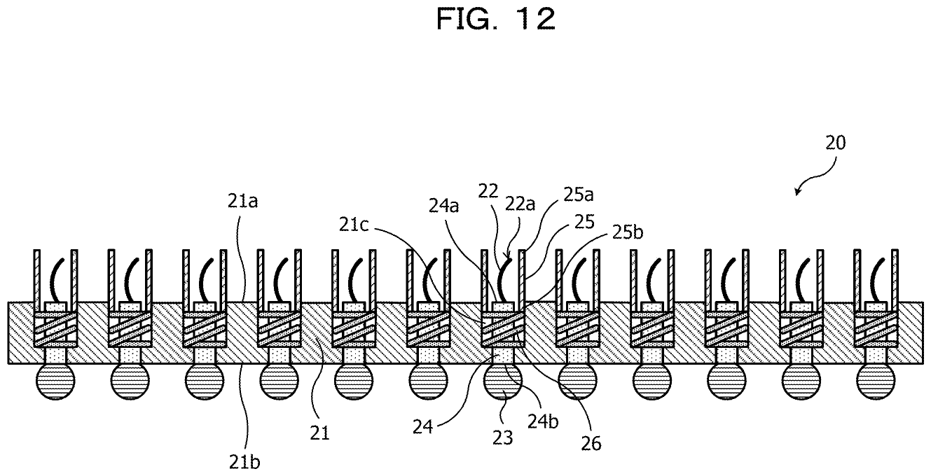

Furthermore, FIGS. 11A, 11B, and 12 are views illustrating the configuration example of the socket according to the first embodiment. In FIG. 11A, a plan view of a main part of the configuration example of the socket according to the first embodiment is schematically illustrated, and in FIG. 11B, a side view of the main part of the configuration example of the socket according to the first embodiment is schematically illustrated. In FIG. 12, a cross-sectional view taken along a line XII-XII of FIG. 11A is schematically illustrated.

For example, as illustrated in FIGS. 10A and 10B, the semiconductor device 10 is provided with the plurality of pads 11 arranged in a matrix on the side of the surface 10a of the semiconductor device 10. Such a semiconductor device 10 provided with the plurality of pads 11 is connected to the socket 20. Note that the plurality of pads 11 provided on the side of the surface 10a of the semiconductor device 10 may be divided into pads 11 positioned in a central portion 12 and pads 11 positioned in an outer peripheral portion 13 outside the central portion 12, as illustrated in FIG. 10A.

For example, as illustrated in FIGS. 11A, 11B, and 12, the socket 20 is provided with the plurality of terminal portions 22 arranged in a matrix. The plurality of terminal portions 22 is provided so as to be positioned corresponding to the plurality of pads 11 of the semiconductor device 10 connected to the socket 20.

As illustrated in FIG. 12, each of the plurality of terminal portions 22 is connected to the one end surface 24a of the conductor portion 24 provided in the base portion 21 and is supported by the conductor portion 24. Each of the plurality of terminal portions 22 is provided on the side of the surface 21a of the base portion 21, and has flexibility against a load from the outside on the side of the surface 21a, for example, a load from the side of the semiconductor device 10 connected to the socket 20. Each of the plurality of terminal portions 22 is surrounded in a wall shape by the tubular barrier portion 25 supported by the elastic portion 26 provided in the recess 21c of the base portion 21. Each barrier portion 25 is provided so that a part on the side of the end 25b supported by the elastic portion 26 is positioned in the recess 21c of the base portion 21. Each barrier portion 25 is energized independently from each other by the elastic portion 26 in a direction from the base portion 21 toward the outside on the side of the surface 21a, for example, in the direction toward the semiconductor device 10 connected to the socket 20. The end 25a of each barrier portion 25 on the side connected to the semiconductor device 10 is positioned higher than the tip portion 22a of the terminal portion 22 relative to the surface 21a of the base portion 21 in the no-load state. The another end surface 24b of the conductor portion 24, to which each of the plurality of terminal portions 22 is connected, is positioned on the surface 21b of the base portion 21, and the bump 23 is connected to the end surface 24b.

The socket 20 has, for example, the configuration as illustrated in FIGS. 11A, 11B, and 12 with respect to the semiconductor device 10 as illustrated in FIGS. 10A and 10B. Note that the configuration of the socket 20 is not limited to this.

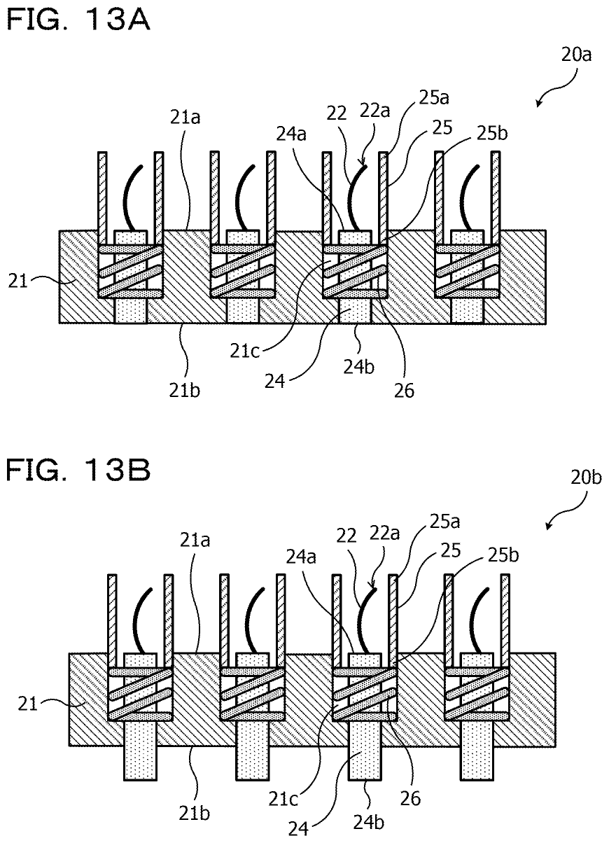

FIGS. 13A and 13B are views illustrating a modification of the socket according to the first embodiment. In FIG. 13A, a cross-sectional view of a main part of a first modification of the socket according to the first embodiment is schematically illustrated. In FIG. 13B, a cross-sectional view of a main part of a second modification of the socket according to the first embodiment is schematically illustrated.

In FIG. 13A, an example of a socket 20a before being connected to another part is illustrated. As the socket 20a illustrated in FIG. 13A, the socket 20a before being connected to another part does not necessarily have to be provided with the bump 23. The bump 23 may be provided on a side of a mating part to which the socket 20a is connected, for example, on a side of a substrate 30 described later. In this case, when the socket 20a and the mating component are connected, the bump 23 provided on the side of the mating part is connected to the end surface 24b of the conductor portion 24 of the socket 20a by reflow or the like.

Furthermore, in FIG. 13B, an example of a socket 20b before being connected to another part is illustrated. As in the socket 20b illustrated in FIG. 13B, the conductor portion 24 may have the end surface 24b thereof positioned outside the surface 21b of the base portion 21. For example, the conductor portion 24 may have a part thereof protruded from the surface 21b of the base portion 21. A portion of the conductor portion 24 protruded from the surface 21b of the base portion 21 in this way may be used as a post electrode used for connection with a mating part such as the substrate 30 described later.

In the semiconductor apparatus 1, the socket 20a having the configuration as illustrated in FIG. 13A or the socket 20b having the configuration as illustrated in FIG. 13B may be used as the socket connected to the semiconductor device 10, in addition to the socket 20 having the configuration described above.

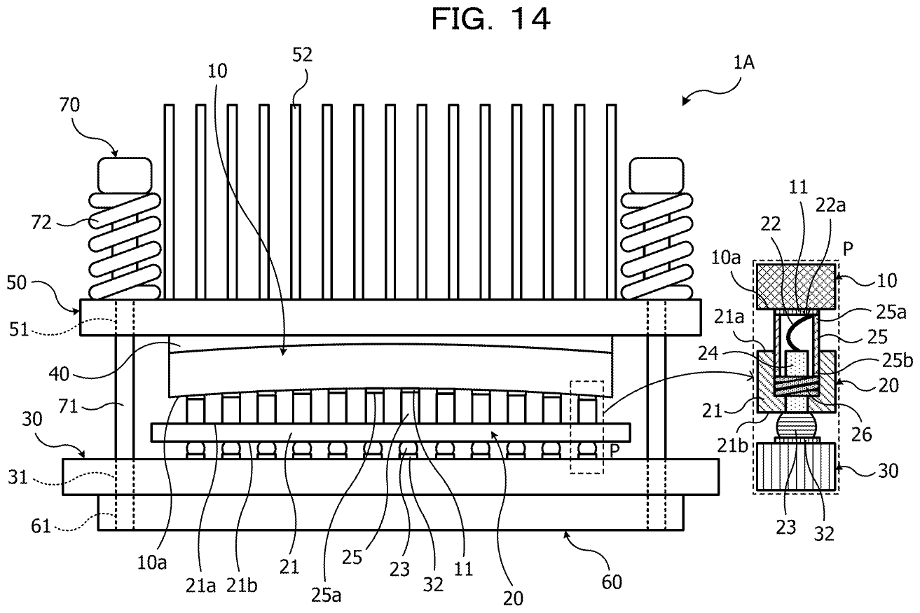

Subsequently, a configuration example of the semiconductor apparatus 1 in which the socket 20 or the like is used will be described. FIG. 14 is a view illustrating the configuration example of the semiconductor apparatus according to the first embodiment. In FIG. 14, a side view of a main part of the configuration example of the semiconductor apparatus according to the first embodiment is schematically illustrated. For convenience, in FIG. 14, an enlarged cross-sectional view of a P portion of the semiconductor apparatus is also schematically illustrated.

A semiconductor apparatus 1A illustrated in FIG. 14 includes the semiconductor device 10 and the socket 20. The semiconductor apparatus 1A further includes the substrate 30, a thermal bonding material 40, a cooling part 50, a plate 60, and fixing parts 70.

For the semiconductor device 10 and the socket 20, those having the configurations described above are used. The semiconductor device 10 is provided on the side of the surface 21a of the base portion 21 of the socket 20, on which the plurality of terminal portions 22 and the plurality of tubular barrier portions 25 each of which surrounds corresponding one of the plurality of terminal portions 22 in a wall shape and which is supported and energized by the elastic portions 26 are provided. The semiconductor device 10 is provided with the plurality of pads 11 at positions corresponding to the plurality of terminal portions 22 and the plurality of barrier portions 25 of the socket 20. The socket 20 is arranged on the side of the plurality of pads 11 of the semiconductor device 10 while aligning the positions of corresponding ones of the plurality of terminal portions 22, the plurality of barrier portions 25, and the plurality of pads 11 with each other. On the side of the surface 21b of the base portion 21 of the socket 20 opposite to the side of the surface 21a on which the plurality of terminal portions 22 and the plurality of barrier portions 25 are provided, the plurality of bumps 23 each of which is electrically connected to corresponding one of the plurality of terminal portions 22 through the conductor portion 24 is provided.

The substrate 30 is provided on the side of the socket 20 opposite to the side of the semiconductor device 10. For the substrate 30, a circuit board such as a printed circuit board is used. The bumps 23 of the socket 20 are bonded to pads 32 provided on the substrate 30 by reflow or the like. Alternatively, the bumps 23 provided on the pads 32 of the substrate 30 are bonded to the end surface 24b of the conductor portion 24 of the socket 20 by reflow or the like. The substrate 30 is provided with through holes 31 into which the fixing parts 70 are inserted, outside a region facing the semiconductor device 10 and the socket 20, for example, at ends such as four corners of the substrate 30.

The thermal bonding material 40 is provided on the side of the semiconductor device 10 opposite to a side of the socket 20. For the thermal bonding material 40, various TIMs such as a heat conductive sheet and a heat conductive paste are used. The cooling part 50 is provided on a side of the thermal bonding material 40 opposite to the side of the semiconductor device 10. For the cooling part 50, a metal material such as Cu, Cu alloy, Al, or Al alloy is used. The cooling part 50 is provided with fins 52 having various shapes. The cooling part 50 is provided with through holes 51 into which the fixing parts 70 are inserted at portions corresponding to the through holes 31 of the substrate 30 outside the region facing the semiconductor device 10 and the socket 20, for example, at ends such as four corners of the cooling part 50. Note that, for the cooling part 50, for example, one provided with a flow path for circulating a liquid or gas refrigerant in a block of a metal material or the like may be used.

The plate 60 is provided on a side of the substrate 30 opposite to the side of the socket 20. For the plate 60, a material having relatively high rigidity such as metal is used. The plate 60 is provided with screw holes 61 into which tip portions of the fixing parts 70 are screwed at portions corresponding to the through holes 51 of the cooling part 50 and the through holes 31 of the substrate 30, for example, ends such as four corners of the plate 60.

For the fixing part 70, a spring-loaded screw including a screw 71 provided with a screw thread at a tip portion and a spring 72 into which the screw 71 is inserted is used. The screw 71 inserted into the spring 72 is inserted into the through hole 51 of the cooling part 50 and the through hole 31 of the substrate 30, and the tip portion of the screw 71 is screwed into the screw hole 61 of the plate 60. The spring 72 is sandwiched between a head of the screw 71 and the cooling part 50 to energize the cooling part 50 toward a side of the plate 60.

In the semiconductor apparatus 1A, a screwing amount of the fixing parts 70 relative to the plate 60 is adjusted within an appropriate range, and the thermal bonding material 40, the semiconductor device 10, the socket 20, and the substrate 30 are sandwiched between the cooling part 50 and the plate 60. The semiconductor device 10 is brought close to the socket 20 as the screwing amount of the fixing parts 70 increases, and a load from the side of the semiconductor device 10 is applied to the socket 20.

As described above, the barrier portion 25 of the socket 20 has the end 25a positioned higher than the terminal portion 22 in the no-load state. Therefore, the semiconductor device 10 brought close to the base portion 21 of the socket 20 is first connected to the end 25a of the barrier portion 25 surrounding the terminal portion 22. When the semiconductor device 10 is further brought close to the base portion 21, the barrier portion 25 is pushed against the energizing force of the elastic portion 26. When the end 25a of the barrier portion 25 is pushed to a height of the terminal portion 22 in the no-load state, the terminal portion 22 is connected to the pad 11 of the semiconductor device 10. From this state, when the semiconductor device 10 is further brought close to the base portion 21, the barrier portion 25 is further pushed against the energizing force of the elastic portion 26 while maintaining the state where the end 25a of the barrier portion 25 is connected to the semiconductor device 10, and the terminal portion 22 is pushed by the pad 11 of the semiconductor device 10 and bent.

Here, as illustrated in FIG. 14, warpage in a convex shape (also referred to as “convex warpage”) may occur in the semiconductor device 10 from the side of the socket 20 toward a side of the thermal bonding material 40. In a case where such convex warpage occurs in the semiconductor device 10, some of the plurality of pads 11 provided thereon have different gaps from the surface 21a of the base portion 21 of the socket 20. In the example of FIG. 14, since the convex warpage occurs in the semiconductor device 10 from the side of the socket 20 toward the side of the thermal bonding material 40, gaps between the pads 11 and the base portion 21 are smaller in the outer peripheral portion than in the central portion of the semiconductor device 10. In the socket 20, even in a case where some of the plurality of pads 11 have different gaps from the base portion 21 in this way, occurrence of disconnection and a short circuit may be suppressed, and corresponding ones of the pads 11 and the terminal portions 22 may be connected.

For example, at the portion (central portion) of the pads 11 where the gaps from the base portion 21 are relatively large, when the semiconductor device 10 is brought close to the base portion 21, first, the barrier portions 25 surrounding the terminal portions 22 are connected to the semiconductor device 10. Then, when the barrier portions 25 are pushed against the energizing force of the elastic portions 26 and the terminal portions 22 are connected to the pads 11, the terminal portions 22 are pushed by the pads 11 and bent while the connection state between the barrier portions 25 and the semiconductor device 10 is maintained. In the socket 20, the bending terminal portions 22 are surrounded by the barrier portions 25 that are energized by the elastic portions 26 and connected to the semiconductor device 10. Therefore, it is avoided that the terminal portion 22 extends by the elastic force generated by the bending and disengages from the corresponding pad 11, and that the terminal portion 22 extends to and is connected to the pad 11 adjacent to the pad 11 and causes a short circuit.

When the semiconductor device 10 is brought close to the base portion 21, at the portion (outer peripheral portion) of the pads 11 where the gaps from the base portion 21 are relatively small, the barrier portions 25 surrounding the terminal portions 22 are connected to the semiconductor device 10 faster than the portion (central portion) of the pads 11 where the gaps are relatively large. Then, even when the barrier portions 25 are pushed against the energizing force of the elastic portions 26, the terminal portions 22 are connected to the pads 11 at the portion of the pads 11 where the gaps are relatively small faster than the portion of the pads 11 where the gaps are relatively large. From there, the terminal portions 22 are pushed by the pads 11 and bent while the connection state between the barrier portions 25 and the semiconductor device 10 is maintained. At that time, at the portion of the pads 11 where the gaps are relatively small, since bending starts from an earlier stage than the portion of the pads 11 where the gaps are relatively large, and further, the pads 11 are positioned closer to the base portion 21, the bending of the terminal portions 22 is large. In the socket 20, even when the bending of the terminal portions 22 is great in this way, the bending terminal portions 22 are surrounded by the barrier portions 25 that are energized by the elastic portions 26 and connected to the semiconductor device 10. Therefore, it is avoided that, even when the bending of the terminal portion 22 is great, the terminal portion 22 extends by the elastic force generated by the great bending and disengages from the corresponding pad 11, and that the terminal portion 22 extends to and is connected to the pad 11 adjacent to the pad 11 and causes a short circuit.

Note that the terminal portions 22 of the socket 20 move due to the elastic force generated by the bending when being connected to the pads 11 of the semiconductor device 10 while rubbing the surfaces of the pads 11, and wipe the surfaces of the pads 11. With this configuration, a coating film, dust, and the like existing on the surfaces of the pads 11 are removed to expose clean surfaces, and the clean surfaces and the terminal portions 22 are connected, which suppresses an increase in resistance between the pads 11 and the terminal portions 22.

It may also be said that, in the semiconductor apparatus 1A illustrated in FIG. 14, at the portion (central portion) of the pads 11 where the gaps from the base portion 21 are relatively large, the socket 20 is in the state as illustrated in the central view of FIG. 5 and FIGS. 7A and 7B described above, for example. It may also be said that, at the portion (outer peripheral portion) of the pads 11 where the gaps from the base portion 21 are relatively small, the socket 20 is in the state as illustrated in the right view of FIG. 5 and FIGS. 8A and 8B, for example.

In the socket 20 connected to the semiconductor device 10 in which the convex warpage occurs as illustrated in FIG. 14, positions of the ends 25a of the plurality of barrier portions 25 relative to the surface 21a (reference position) of the base portion 21 are positions depending on the gaps between the corresponding plurality of pads 11 and the base portion 21. Therefore, as illustrated in FIG. 14, some of the plurality of barrier portions 25 of the socket 20 connected to the semiconductor device 10 may have the ends 25a at positions different from each other relative to the surface 21a of the base portion 21.

In the semiconductor apparatus 1A, since the socket 20 including the tubular barrier portions 25 that surround the terminal portions 22 in wall shapes and are energized by the elastic portions 26 is used, an insufficient load of the semiconductor device 10 on the socket 20 and disconnection and a short circuit between the terminal portion 22 and the pads 11 are avoided. With this configuration, the high-quality semiconductor apparatus 1A is achieved in which a connection failure between the semiconductor device 10 and the socket 20 is suppressed even when the convex warpage occurs in the semiconductor device 10.

Note that, in a case where the convex warpage occurs in the semiconductor device 10, the semiconductor device 10 (the surface 10a or the pad 11 thereof) has an inclined positional relationship relative to the surface 21a of the base portion 21, and gaps may be partially generated between the semiconductor device 10 and the ends 25a of the barrier portions 25 connected to the semiconductor device 10. Note that the warpage (a height difference relative to the surface 21a) in a region of the pads 11 of the semiconductor device 10 and in the vicinity of the pads 11 is one order of magnitude or more smaller than the thickness of the terminal portions 22 (the tip portions 22a thereof). Therefore, it is possible to suppress protrusion of the terminal portion 22 from the gap generated between the semiconductor device 10 and the end 25a of the barrier portion 25.

Here, the case has been taken as an example where the convex warpage occurs in the semiconductor device 10. In addition, according to the socket 20, also in a case where warpage in a concave shape (also referred to as “concave warpage”) occurs in the semiconductor device 10 from the side of the thermal bonding material 40 toward the side of the socket 20, a connection failure between the semiconductor device 10 and the socket 20 may be suppressed similarly.

### Second Embodiment

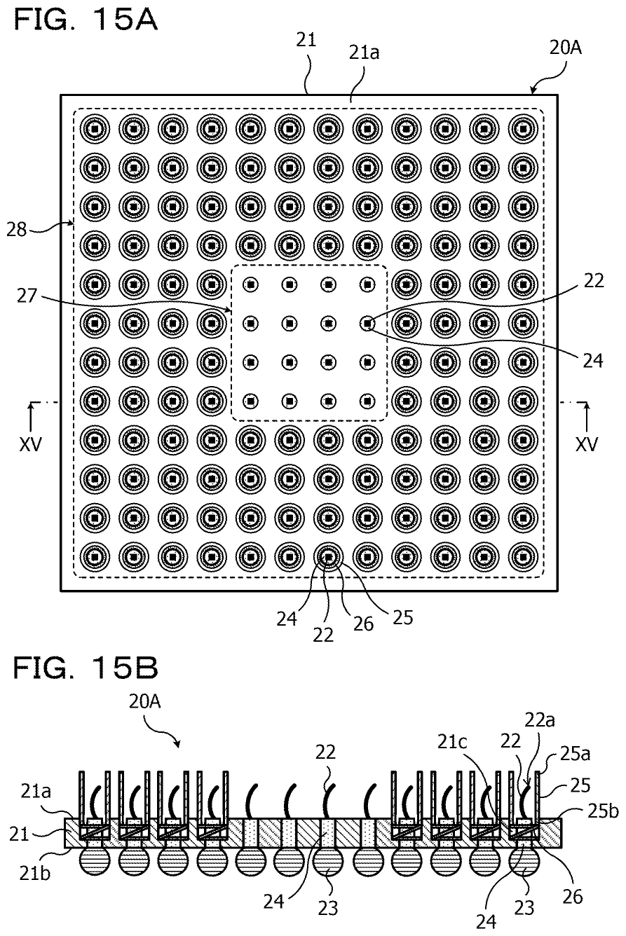

FIGS. 15A and 15B are views illustrating a first example of a socket according to a second embodiment. In FIG. 15A, a plan view of a main part of the first example of the socket according to the second embodiment is schematically illustrated, and in FIG. 15B, a cross-sectional view taken along a line XV-XV of FIG. 15A is schematically illustrated.

A socket 20A illustrated in FIGS. 15A and 15B has a central portion 27 and an outer peripheral portion 28 outside thereof respectively corresponding to the central portion 12 and the outer peripheral portion 13 outside thereof of the semiconductor device 10 as illustrated in FIG. 10A described above. Each of the central portion 27 and the outer peripheral portion 28 of the socket 20A is provided with a plurality of terminal portions 22 having flexibility, corresponding to the plurality of pads 11 positioned in the central portion 12 and the outer peripheral portion 13 of the semiconductor device 10. In the socket 20A, for the terminal portions 22 positioned in the outer peripheral portion 28, a structure is adopted in which conductor portions 24 provided on a base portion 21 and supporting the terminal portions 22, tubular barrier portions 25 surrounding the terminal portions 22, and elastic portions 26 supporting and energizing, the barrier portions 25 are provided. In the socket 20A, for the terminal portions 22 positioned in the central portion 27, a structure is adopted in which the terminal portions 22 are supported by the conductor portions 24 provided on the base portion 21. The socket 20A is different from the socket 20 described in the first embodiment above in that the socket 20A has such a configuration.

Such a socket 20A is provided on the side of the pads 11 of the semiconductor device 10 so that the terminal portions 22 and the pads 11 face each other. Then, a load is applied in a direction from the semiconductor device 10 toward the socket 20A, and corresponding ones of the pads 11 and the terminal portions 22 of the semiconductor device 10 and the socket 20A are connected.

For example, a case is considered where warpage occurs so that gaps from the base portion 21 are smaller in the outer peripheral portion 13 than in the central portion 12 of the semiconductor device 10, for example, convex warpage occurs in the semiconductor device 10 connected to the socket 20A. In this case, in the socket 20A, since the terminal portions 22 in the outer peripheral portion 28 are bent greater than the terminal portions 22 in the central portion 27, the elastic force of the terminal portions 22 in the outer peripheral portion 28 is larger. In the socket 20A, for the terminal portions 22 in the outer peripheral portion 28 that have such large elastic force, the barrier portions 25 surrounding the terminal portions 22 and the elastic portions 26 supporting and energizing the barrier portions 25 are provided.

When the semiconductor device 10 is brought close to the socket 20A, the barrier portions 25 in the outer peripheral portion 28 are energized by the elastic portions 26 and connected to the semiconductor device 10, and pushed against energizing force of the elastic portions 26 while maintaining the state of being connected to the semiconductor device 10. The terminal portions 22 in the outer peripheral portion 28 are surrounded by the barrier portions 25 connected to the semiconductor device 10 until and even after the semiconductor device 10 is brought close to the socket 20A, and the terminal portions 22 in the outer peripheral portion 28 are brought into contact with the pads 11, and further rub the surfaces of the pads 11 and are connected to the surfaces of the pads 11. Therefore, it is avoided that the terminal portion 22 in the outer peripheral portion 28, which is bent greater than the terminal portion 22 in the central portion 27, extends by the elastic force generated by the bending and disengages from the pad 11, and that the terminal portion 22 extends to and is connected to the pad 11 adjacent to the pad 11 and causes a short circuit.

On the other hand, in a case where convex warpage occurs in the semiconductor device 10, at the terminal portion 22 in the central portion 12, where the bending is smaller than that of the terminal portion 22 in the outer peripheral portion 28, it is unlikely that disengagement from the corresponding pad 11 and a short circuit due to extension to the adjacent pad 11 will occur. Therefore, in the socket 20A, for the terminal portions 22 in the central portion 12, a structure is adopted in which the barrier portions 25 and the elastic portions 26 are not provided and the terminal portions 22 are supported by the conductor portions 24.

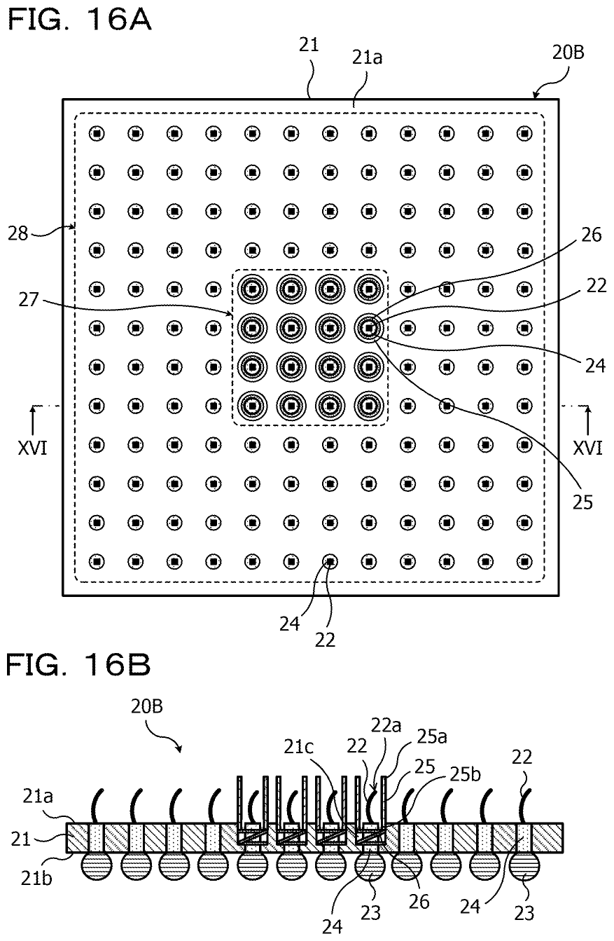

FIGS. 16A and 16B are views illustrating a second example of the socket according to the second embodiment. In FIG. 16A, a plan view of a main part of the second example of the socket according to the second embodiment is schematically illustrated, and in FIG. 16B, a cross-sectional view taken along a line XVI-XVI of FIG. 16A is schematically illustrated. In a socket 20B illustrated in FIGS. 16A and 16B, for the terminal portions 22 positioned in the central portion 27, a structure is adopted in which the conductor portions 24 provided on the base portion 21 and supporting the terminal portions 22, the tubular barrier portions 25 surrounding the terminal portions 22, and the elastic portions 26 supporting and energizing the barrier portions 25 are provided. In the socket 20B, for the terminal portions 22 positioned in the outer peripheral portion 28, a structure is adopted in which the terminal portions 22 are supported by the conductor portions 24 provided on the base portion 21. The socket 20B is different from the socket 20A described above in that the socket 20B has such a configuration.

Such a socket 20B is provided on the side of the pads 11 of the semiconductor device 10 so that the terminal portions 22 and the pads 11 face each other. Then, a load is applied in the direction from the semiconductor device 10 toward the socket 20B, and corresponding ones of the pads 11 and the terminal portions 22 of the semiconductor device 10 and the socket 20B are connected.

For example, a case is considered where warpage occurs so that gaps from the base portion 21 are smaller in the central portion 12 than in the outer peripheral portion 13 of the semiconductor device 10, for example, concave warpage occurs in the semiconductor device 10 connected to the socket 20B. In this case, in the socket 20B, since the terminal portions 22 in the central portion 27 are bent greater than the terminal portions 22 in the outer peripheral portion 28, the elastic force of the terminal portions 22 in the central portion 27 is larger. In the socket 20B, for the terminal portions 22 in the central portion 27 that have such large elastic force, the barrier portions 25 surrounding the terminal portions 22 and the elastic portions 26 supporting and energizing the barrier portions 25 are provided.

When the semiconductor device 10 is brought close to the socket 208, the barrier portions 25 in the central portion 27 are energized by the elastic portions 26 and connected to the semiconductor device 10, and pushed against the energizing force of the elastic portions 26 while maintaining the state of being connected to the semiconductor device 10. The terminal portions 22 in the central portion 27 are surrounded by the barrier portions 25 connected to the semiconductor device 10 until and even after the semiconductor device 10 is brought close to the socket 20B, and the terminal portions 22 in the central portion 27 are brought into contact with the pads 11, and further rub the surfaces of the pads 11 and are connected to the surfaces of the pads 11. Therefore, it is avoided that the terminal portion 22 in the central portion 27, which is bent greater than the terminal portion 22 in the outer peripheral portion 28, extends by the elastic force generated by the bending and disengages from the corresponding pad 11, and that the terminal portion 22 extends to and is connected to the pad 11 adjacent to the pad 11 and causes a short circuit.

On the other hand, in a case where concave warpage occurs in the semiconductor device 10, at the terminal portion 22 in the outer peripheral portion 28, where the bending is smaller than that of the terminal portion 22 in the central portion 27, it is unlikely that disengagement from the corresponding pad 11 and a short circuit due to extension to the adjacent pad 11 will occur. Therefore, in the socket 20B, for the terminal portions 22 in the outer peripheral portion 28, a structure is adopted in which the barrier portions 25 and the elastic portions 26 are not provided and the terminal portions 22 are supported by the conductor portions 24.

For the socket connected to the semiconductor device 10, in addition to the socket 20 described in the first embodiment above, the socket 20A (FIGS. 15A and 15B) or the socket 20B (FIGS. 16A and 16B) described in the second embodiment may be used on the basis of warpage that occurs in the semiconductor device 10. For example, according to the example of FIG. 14 described above, the semiconductor apparatus is obtained in which the thermal bonding material 40, the semiconductor device 10, the socket 20A or the socket 20B, and the substrate 30 are sandwiched between the cooling part 50 and the plate 60 fixed by the fixing parts 70.

Note that, according to the example of FIG. 13A described above, it is possible not to provide the bumps 23 in the socket 20A and the socket 20B before being connected to another part. Furthermore, according to the example of FIG. 138 described above, a part of the conductor portion 24 of the socket 20A and the socket 20B is protruded from the surface 21b of the base portion 21, and the protruded portion of the conductor portion 24 may be used as a post electrode.

### Third Embodiment

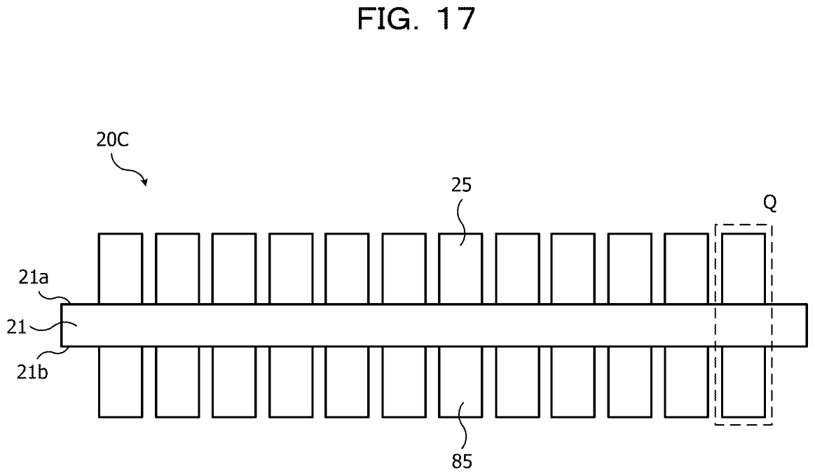

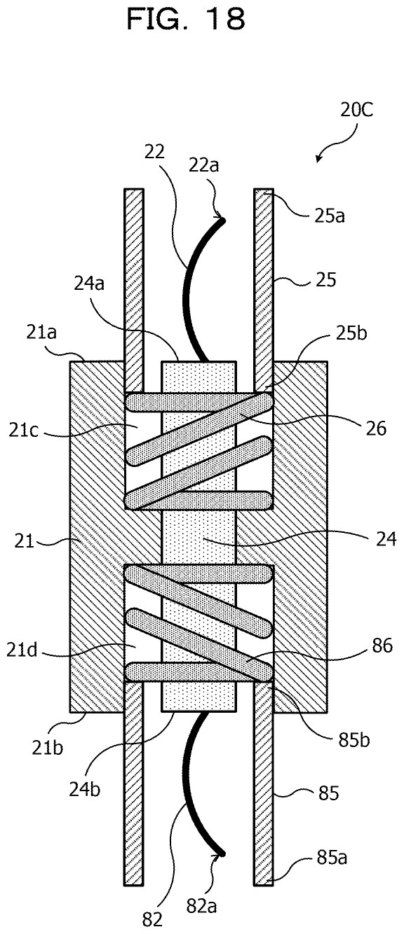

FIGS. 17 and 18 are views illustrating an example of a socket according to a third embodiment. In FIG. 17, a side view of a main part of an example of the socket according to the third embodiment is schematically illustrated. In FIG. 18, a cross-sectional view of a main part of an example of the socket according to the third embodiment is schematically illustrated. Note that FIG. 18 schematically illustrates an enlarged cross-sectional view of a Q portion of FIG. 17.

A socket 20C illustrated in FIGS. 17 and 18 has a configuration in which barrier portions 25 surrounding terminal portions 22 are provided on a side of one surface 21a of a base portion 21, and barrier portions 85 surrounding terminal portions 82 are provided on a side of another surface 21b of the base portion 21.

As illustrated in FIG. 18, the base portion 21 is provided with, for example, a recess 21c and a recess 21d on the side of the surface 21a and the side of the surface 21b, respectively, and a conductor portion 24 is provided so as to penetrate between the recess 21c and the recess 21d. The terminal portion 22 on the side of the surface 21a of the base portion 21 is connected to and supported by one end surface 24a of the conductor portion 24. The terminal portion 82 on the side of the surface 21b of the base portion 21 is connected to and supported by another end surface 24b of the conductor portion 24. The terminal portion 22 on the side of the surface 21a of the base portion 21 is surrounded by the tubular barrier portion 25 having an end 25b supported and energized by an elastic portion 26 provided in the recess 21c. The terminal portion 82 on the side of the surface 21b of the base portion 21 is surrounded by the tubular barrier portion 85 having an end 85b supported and energized by an elastic portion 86 provided in the recess 21d. In a no-load state, an end 25a of the barrier portion 25 is positioned higher than a tip portion 22a of the terminal portion 22 relative to the surface 21a of the base portion 21. In the no-load state, an end 85a of the barrier portion 85 is positioned higher than a tip portion 82a of the terminal portion 82 relative to the surface 21b of the base portion 21. The barrier portion 25 and the barrier portion 85 are separately energized by the elastic portion 26 and the elastic portion 86, respectively, so as to be displaced independently from each other relative to loads from the outside on the side of the surface 21a and the outside on the side of the surface 21b of the base portion 21.

The structure as illustrated in FIG. 18 is provided at each of positions corresponding to a plurality of pads 11 of a semiconductor device 10 described later connected to the side of the surface 21a of the base portion 21 of the socket 20C and a plurality of pads 32 of a substrate 30 described later connected to the side of the surface 21b of the base portion 21.

The socket 20C is different from the socket 20 described in the first embodiment above in that the socket 20C has such a configuration.

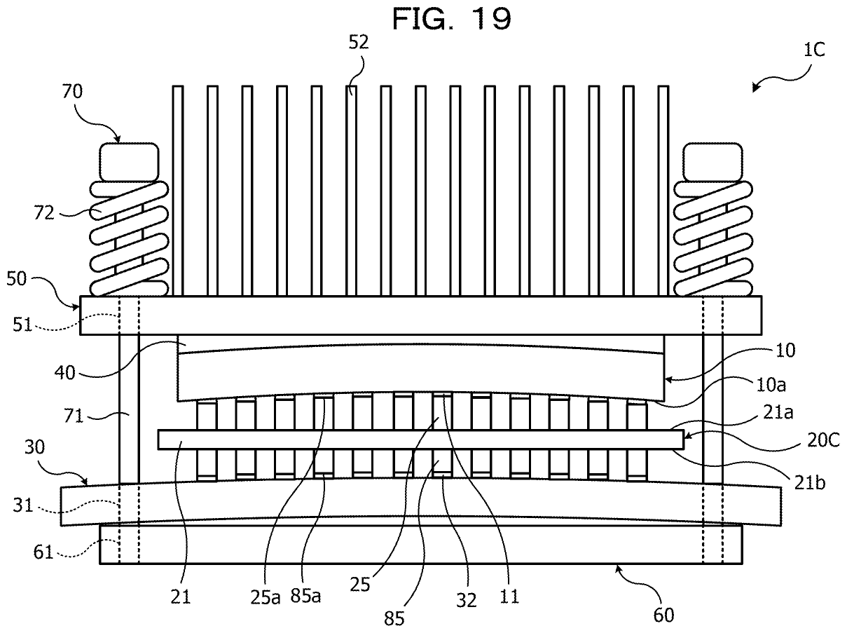

FIG. 19 is a view illustrating a configuration example of a semiconductor apparatus according to the third embodiment. In FIG. 19, a side view of a main part of the configuration example of the semiconductor apparatus according to the third embodiment is schematically illustrated.

A semiconductor apparatus 1C illustrated in FIG. 19 includes the semiconductor device 10 and the socket 20C. The semiconductor apparatus 1C further includes the substrate 30, a thermal bonding material 40, a cooling part 50, a plate 60, and fixing parts 70.

In the semiconductor apparatus 1C, the semiconductor device 10 is provided on the side of the surface 21a of the base portion 21 of the socket 20C, on which the plurality of terminal portions 22 and the plurality of tubular barrier portions 25 each of which surrounds corresponding one of the plurality of terminal portions 22 in a wall shape and which is supported and energized by the elastic portions 26 are provided. The semiconductor device 10 is provided with the plurality of pads 11 at positions corresponding to the plurality of terminal portions 22 and the plurality of barrier portions 25 of the socket 20C. The socket 20C is arranged on the side of the plurality of pads 11 of the semiconductor device 10 while aligning the positions of corresponding ones of the plurality of terminal portions 22, the plurality of barrier portions 25, and the plurality of pads 11 with each other.

In the semiconductor apparatus 1C, the substrate 30 is provided on the side of the surface 21b of the base portion 21 of the socket 20C, on which the plurality of terminal portions 82 and the plurality of tubular barrier portions 85 each of which surrounds corresponding one of the plurality of terminal portions 82 in a wall shape and which is supported and energized by the elastic portions 86 are provided. The substrate 30 is provided with the plurality of pads 32 at positions corresponding to the plurality of terminal portions 82 and the plurality of barrier portions 85 of the socket 20C. The socket 20C is arranged on a side of the plurality of pads 32 of the substrate 30 while aligning the positions of corresponding ones of the plurality of terminal portions 82, the plurality of barrier portions 85, and the plurality of pads 32 with each other. The substrate 30 is provided with through holes 31 into which the fixing parts 70 are inserted at portions corresponding to the outside of the semiconductor device 10 and the socket 20C.

In the semiconductor apparatus 1C, the cooling part 50 is provided on a side of the semiconductor device 10 opposite to a side of the socket 20C via the thermal bonding material 40. For the thermal bonding material 40, TIMs are used. For the cooling part 50, a metal material is used. The cooling part 50 is provided with fins 52 and through holes 51 into which the fixing parts 70 are inserted at portions corresponding to the through holes 31 of the substrate 30. Note that, for the cooling part 50, for example, one provided with a flow path for circulating a refrigerant in a block of a metal material or the like may be used.

In the semiconductor apparatus 1C, the plate 60 is provided on a side of the substrate 30 opposite to the side of the socket 20C. For the plate 60, a material having high rigidity is used. The plate 60 is provided with screw holes 61 into which tip portions of the fixing parts 70 are screwed at portions corresponding to the through holes 51 of the cooling, part 50 and the through holes 31 of the substrate 30.

For the fixing part 70, a spring-loaded screw including a screw 71 and a spring 72 is used. The screw 71 inserted into the spring 72 is inserted into the through hole 51 of the cooling part 50 and the through hole 31 of the substrate 30, and the tip portion of the screw 71 is screwed into the screw hole 61 of the plate 60. The spring 72 is sandwiched between a head of the screw 71 and the cooling part 50 to energize the cooling part 50 toward a side of the plate 60.

In the semiconductor apparatus 1C, a screwing amount of the fixing parts 70 relative to the plate 60 is adjusted within an appropriate range, and the thermal bonding material 40, the semiconductor device 10, the socket 20C, and the substrate 30 are sandwiched between the cooling part 50 and the plate 60. The semiconductor device 10 and the substrate 30 are brought close to the socket 20C as the screwing amount of the fixing parts 70 increases, and loads from the side of the semiconductor device 10 and the side of the substrate 30 are applied to the socket 20C.

Here, as illustrated in FIG. 19, warpage may occur in the semiconductor device 10 and the substrate 30. In FIG. 19, as an example, a case is illustrated where convex warpage occurs in the semiconductor device 10 from the side of the socket 20C toward a side of the thermal bonding material 40, and convex warpage occurs in the substrate 30 from the side of the plate 60 toward the side of the socket 20C.

In a case where the convex warpage occurs in the semiconductor device 10, some of the plurality of pads 11 provided thereon have different gaps from the surface 21a of the base portion 21 of the socket 20C. In the socket 20C, even in a case where some of the plurality of pads 11 have different gaps from the surface 21a of the base portion 21, each of the plurality of barrier portions 25 at the portions having different gaps is pushed against the energizing force of the elastic portion 26 (FIG. 18), against the load from the side of the semiconductor device 10. Therefore, when the semiconductor device 10 is brought close to the socket 20C, each of the plurality of barrier portions 25 at the portions having different gaps is connected to the semiconductor device 10 and then the connection state with the semiconductor device 10 is maintained. The terminal portions 22 are surrounded by the barrier portions 25 connected to the semiconductor device 10 until and even after the semiconductor device 10 is brought close to the socket 20C, and the terminal portions 22 (FIG. 18) are connected to the corresponding pads 11. Therefore, it is avoided that the terminal portion 22 which is bent with the connection to the pad 11 extends by the elastic force generated by the bending and disengages from the corresponding pad 11, and that the terminal portion 22 extends to and is connected to the pad 11 adjacent to the pad 11 and causes a short circuit.

Note that the terminal portions 22 of the socket 20C move due to the elastic force generated by the bending when being connected to the pads 11 of the semiconductor device 10 while rubbing surfaces of the pads 11, and wipe the surfaces of the pads 11. With this configuration, a coating film, dust, and the like existing on the surfaces of the pads 11 are removed to expose clean surfaces, and the clean surfaces and the terminal portions 22 are connected, which suppresses an increase in resistance between the pads 11 and the terminal portions 22.

In a case where the convex warpage occurs in the substrate 30, some of the plurality of pads 32 provided thereon have different gaps from the surface 21b of the base portion 21 of the socket 20C. In the socket 20C, even in a case where some of the plurality of pads 32 have different gaps from the surface 21b of the base portion 21, each of the plurality of barrier portions 85 at the portions having different gaps is pushed against the energizing force of the elastic portion 86 (FIG. 18), against the load from the side of the substrate 30. Therefore, when the substrate 30 is brought close to the socket 20C, each of the plurality of barrier portions 85 at the portions having different gaps is connected to the substrate 30 and then the connection state with the substrate 30 is maintained. The terminal portions 82 are surrounded by the barrier portions 85 connected to the substrate 30 until and even after the substrate 30 is brought close to the socket 20C, and the terminal portions 82 (FIG. 18) are connected to the corresponding pads 32. Therefore, it is avoided that the terminal portion 82 which is bent with the connection to the pad 32 extends by the elastic force generated by the bending and disengages from the corresponding pad 32, and that the terminal portion 82 extends to and is connected to the pad 32 adjacent to the pad 32 and causes a short circuit.

Note that the terminal portions 82 of the socket 20C move due to the elastic force generated by the bending when being connected to the pads 32 of the substrate 30 while rubbing surfaces of the pads 32, and wipe the surfaces of the pads 32. With this configuration, a coating film, dust, and the like existing on the surfaces of the pads 32 are removed to expose clean surfaces, and the clean surfaces and the terminal portions 82 are connected, which suppresses an increase in resistance between the pads 32 and the terminal portions 82.

According to the socket 20C, not only in a case where the convex warpage occurs in the semiconductor device 10, but also in a case where the convex warpage occurs in the substrate 30, it is possible to connect corresponding ones of the pads 11 and the terminal portions 22 and connect corresponding ones of the pads 32 and the terminal portions 82 while suppressing occurrence of disconnection and a short circuit. With this configuration, the high-quality semiconductor apparatus 1C is achieved in which both a connection failure between the semiconductor device 10 and the socket 20C and a connection failure between the substrate 30 and the socket 20C are suppressed even when the convex warpage occurs in the semiconductor device 10 and the substrate 30.

Here, the case has been taken as an example where the convex warpage occurs in the semiconductor device 10 and the substrate 30. In addition, according to the socket 20C, also in a case where concave warpage occurs in the semiconductor device 10 and a case where concave warpage occurs in the substrate 30, a connection failure between them and the socket 20C may be suppressed similarly.

Note that, according to the examples of FIGS. 15A to 16B described above, the structure as illustrated in FIG. 18 may be provided in an outer peripheral portion of the socket 20C corresponding to the outer peripheral portion 13 (FIG. 10A) of the semiconductor device 10, or in a central portion of the socket 20C corresponding to the central portion 12 (FIG. 10A) of the semiconductor device 10.

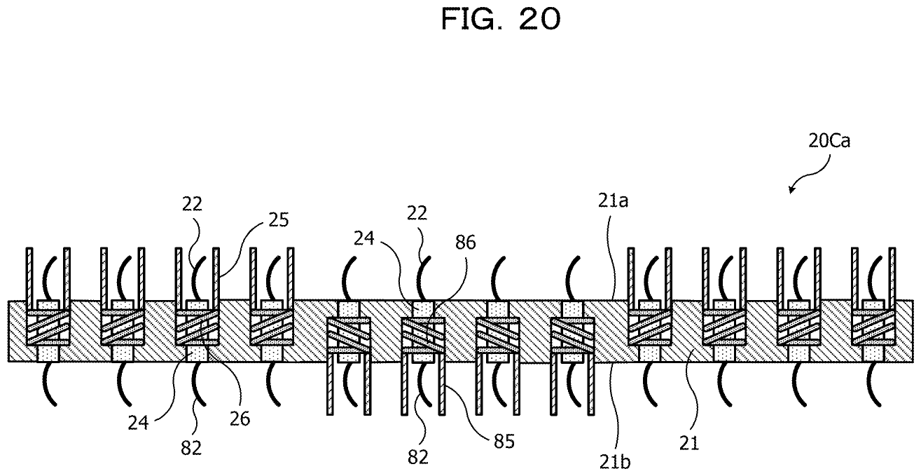

Furthermore, FIG. 20 is a view illustrating a modification of the socket according to the third embodiment. In FIG. 20, a cross-sectional view of a main part of the modification of the socket according to the third embodiment is schematically illustrated.

For example, in a case where convex warpage occurs in the semiconductor device 10 and the substrate 30 as in the semiconductor apparatus 1C illustrated in FIG. 19 described above, a socket 20Ca as illustrated in FIG. 20 may also be used instead of the socket 20C.

In the socket 20Ca illustrated in FIG. 20, according to the examples of FIGS. 15A and 15B described above, a structure is adopted in which the conductor portions 24 supporting the terminal portions 22, the tubular barrier portions 25 surrounding the terminal portions 22, and the elastic portions 26 supporting and energizing the barrier portions 25 are provided in a region corresponding to the outer peripheral portion of the semiconductor device 10 on the side of the surface 21a of the base portion 21. A structure is adopted in which the terminal portions 22 are supported by the conductor portions 24 in a region corresponding to the central portion of the semiconductor device 10 on the side of the surface 21a of the base portion 21. With this configuration, a connection failure may be suppressed between the pads 11 of the semiconductor device 10 in which convex warpage occurs such that the gaps from the surface 21a of the base portion 21 are small in the outer peripheral portion and large in the central portion, and the terminal portions 22 on the side of the surface 21a of the socket 20Ca.

Furthermore, in the socket 20Ca illustrated in FIG. 20, according to the example of FIGS. 16A and 16B described above, a structure is adopted in which the conductor portions 24 supporting the terminal portions 82, the tubular barrier portions 85 surrounding the terminal portions 82, and the elastic portions 86 supporting and energizing the barrier portions 85 are provided in a region corresponding to a central portion of the substrate 30 on the side of the surface 21b of the base portion 21. A structure is adopted in which the terminal portions 82 are supported by the conductor portions 24 in a region corresponding to an outer peripheral portion of the substrate 30 on the side of the surface 21b of the base portion 21. With this configuration, a connection failure may be suppressed between the pads 32 of the substrate 30 in which convex warpage occurs such that the gaps from the surface 21b of the base portion 21 are small in the central portion and large in the outer peripheral portion, and the terminal portions 82 on the side of the surface 21b of the socket 20Ca.

As the socket 20Ca, it is possible to change each of the configuration of the base portion 21 on the side of the surface 21a and the configuration of the base portion 21 on the side of the surface 21b on the basis of the warpage that occurs in the semiconductor device 10 and the substrate 30.

Here, the case has been taken as an example where the convex warpage occurs in the semiconductor device 10 and the substrate 30. In addition, in a case where the concave warpage occurs in the semiconductor device 10, a configuration may be adopted in which, on the side of the surface 21a of the base portion 21, the terminal portions 22 supported by the conductor portions 24, the barrier portions 25, and the elastic portions 26 are provided in the central portion, and the terminal portions 22 supported by the conductor portions 24 are provided in the outer peripheral portion. In a case where the concave warpage occurs in the substrate 30, a configuration may be adopted in which, on the side of the surface 21b of the base portion 21, the terminal portions 82 supported by the conductor portions 24, the barrier portions 85, and the elastic portions 86 are provided in the outer peripheral portion, and the terminal portions 82 supported by the conductor portions 24 are provided in the central portion.

### Fourth Embodiment

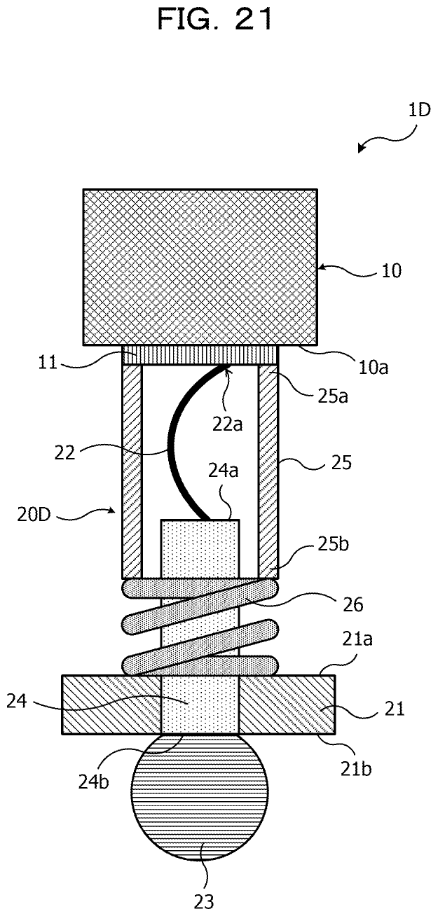

FIG. 21 is a view illustrating an example of a semiconductor apparatus according to a fourth embodiment. In FIG. 21, a cross-sectional view of a main part of an example of the semiconductor apparatus according to the fourth embodiment is schematically illustrated.

A semiconductor apparatus 1D illustrated in FIG. 21 has a configuration in which a socket 20D including a flat plate-shaped base portion 21 is used. The socket 20D includes a conductor portion 24 provided on the flat plate-shaped base portion 21, a terminal portion 22 connected to and supported by the conductor portion 24, a barrier portion 25 surrounding the terminal portion 22, and an elastic portion 26 supporting and energizing the barrier portion 25. The base portion 21 of the socket 20D is not provided with a recess 21c as described above. The semiconductor apparatus 1D is different from the semiconductor apparatus 1 described in the first embodiment above in that the semiconductor apparatus 1D has such a configuration.

The semiconductor apparatus 1D includes the socket 20D and a semiconductor device 10 connected to the socket 20D. In the semiconductor apparatus 1D, for example, a load is applied to the socket 20D from a side of the semiconductor device 10. In the socket 20D used for the semiconductor apparatus 1D, one end 25b of the barrier portion 25 is connected to and fixed to one end of the elastic portion 26. Another end of the elastic portion 26 is connected to and fixed to a surface 21a of the base portion 21. For example, an adhesive is used to connect and fix the elastic portion 26 to the barrier portion 25 and the base portion 21. The end 25b of the barrier portion 25 is supported by the elastic portion 26 on the base portion 21, and the barrier portion 25 is energized by the elastic portion 26 in a direction from the base portion 21 toward the semiconductor device 10. In the barrier portion 25 energized by the elastic portion 26 from a side of the end 25b, another end 25a is connected to the semiconductor device 10 (as an example, a pad 11 thereof).

Note that FIG. 21 illustrates, in a cross-sectional view, an example in which the end 25a of the barrier portion 25 energized by the elastic portion 26 is connected to the pad 11 of the semiconductor device 10, but the portion to which the end 25a of the barrier portion 25 is connected is not limited to this. The end 25a of the barrier portion 25 energized by the elastic portion 26 may be connected to the outside of the pad 11 (a surface 10a in the example of FIG. 21) in addition to the pad 11 of the semiconductor device 10.

Furthermore, a gap, for example, a gap less than a thickness of a tip portion 22a of the terminal portion 22 may partially exist between the semiconductor device 10 and the end 25a of the barrier portion 25 connected to the semiconductor device 10.

In the semiconductor apparatus 1D, by application of a load in a direction from the semiconductor device 10 to the socket 20D, the terminal portion 22 is connected to the pad 11, and the barrier portion 25 surrounding the terminal portion 22 is energized toward the side of the semiconductor device 10 by the elastic portion 26 and connected to the semiconductor device 10. Since the terminal portion 22 is surrounded by the barrier portion 25 connected to the semiconductor device 10, it is avoided that the terminal portion 22 extends by elastic force generated by bending and disengages from the corresponding connected pad 11, and that the terminal portion 22 extends to and is connected to a pad (not illustrated) adjacent to the pad 11 and causes a short circuit. Even when the semiconductor device 10 is brought close to the socket 20D, the barrier portion 25 is pushed toward a side of the base portion 21 against energizing force of the elastic portion 26 while maintaining the state of being connected to the semiconductor device 10. Therefore, it is avoided by the elastic force of the terminal portion 22 that, even when the terminal portion 22 is greatly bent, the tip portion 22a slips on a surface of the pad 11 and extends to the outside of the barrier portion 25. Therefore, it is avoided that the terminal portion 22 disengages from the corresponding connected pad 11 and that the terminal portion 22 is connected to a pad adjacent to the pad 11 and causes a short circuit. By using the socket 20D described above, the high-quality semiconductor apparatus 1D is achieved in which a connection failure between the semiconductor device 10 and the socket 20D is suppressed.

Note that the terminal portion 22 of the socket 20D moves due to the elastic force generated by the bending when being connected to the pad 11 of the semiconductor device 10 while rubbing the surface of the pad 11, and wipes the surface of the pad 11. With this configuration, a coating film, dust, and the like existing on the surface of the pad 11 are removed to expose a clean surface, and the clean surface and the terminal portion 22 are connected, which suppresses an increase in resistance between the pad 11 and the terminal portion 22.

As the socket 20D used for the semiconductor apparatus 1D, the base portion 21 does not necessarily have to be provided with the recess 21c as described above. For example, the elastic portion 26 and the barrier portion 25 does not necessarily have to be provided in the recess 21c as described above, as long as the barrier portion 25 may be displaced according to a load from the side of the semiconductor device 10 or a gap between the semiconductor device 10 and the surface 21a.

The structure of the socket 20D as illustrated in FIG. 21 is provided corresponding to each of the plurality of pads 11 provided on the surface 10a of the semiconductor device 10. For example, according to the example of FIG. 14 described above, the semiconductor apparatus is obtained in which a thermal bonding material 40, the semiconductor device 10, the socket 20D, and a substrate 30 are sandwiched between a cooling part 50 and a plate 60 fixed by fixing parts 70.

Note that, according to the examples of FIGS. 15A to 16B described above, the structure as illustrated in FIG. 21 may be provided in an outer peripheral portion of the socket 20D corresponding to the outer peripheral portion 13 (FIG. 10A) of the semiconductor device 10, or in a central portion of the socket 20D corresponding to the central portion 12 (FIG. 10A) of the semiconductor device 10.

Furthermore, according to the example of FIG. 13A described above, it is possible not to provide bumps 23 in the socket 20D before being connected to another part. Furthermore, according to the example of FIG. 13B described above, a part of the conductor portion 24 of the socket 20D is protruded from a surface 21b of the base portion 21, and the protruded portion of the conductor portion 24 may be used as a post electrode.

Furthermore, according to the examples of FIGS. 17 to 20 described above, a part of the conductor portion 24 may be protruded from the surface 21b (the surface 21b on which a recess 21d is not provided) of the base portion 21, and terminal portions 82, tubular barrier portions 85 surrounding the terminal portions 82, and elastic portions 86 supporting and energizing the barrier portions 85 may be provided on a side of the surface 21b. In that case, according to the example of FIG. 20 described above, the terminal portions 82, the barrier portions 85, and the elastic portions 86 provided on the side of the surface 21b of the base portion 21 may be provided in the central portion or the outer peripheral portion of the socket 20D.

### Fifth Embodiment

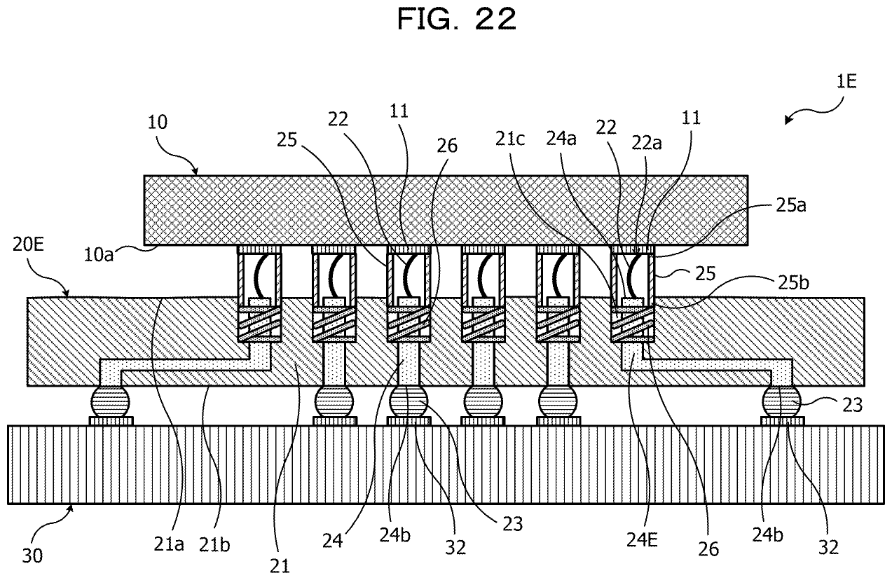

FIG. 22 is a view illustrating an example of a semiconductor apparatus according to a fifth embodiment. In FIG. 22, a cross-sectional view of a main part of an example of the semiconductor apparatus according to the fifth embodiment is schematically illustrated.

A semiconductor apparatus 1E illustrated in FIG. 22 includes a socket 20E, and a semiconductor device 10 and a substrate 30 connected to the socket 20E. The socket 20E has a configuration in which, in addition to conductor portions 24 extending directly below terminal portion 22 to reach a surface 21b of a base portion 21, conductor portions 24E extending directly below terminal portions 22 and being routed laterally inside the base portion 21 to reach the surface 21b are provided. The socket 20E is different from the socket 20 described in the first embodiment above in that the socket 20E has such a configuration.

The semiconductor device 10 is connected to a side of a surface 21a of the base portion 21 of such a socket 20E, and the substrate 30 is connected to a side of the surface 21b of the base portion 21. For example, in the semiconductor apparatus 1E, a load is applied to the socket 20E from a side of the semiconductor device 10.

Corresponding to each of a plurality of pads 11 provided on the semiconductor device 10, the terminal portion 22 on a side of the surface 21a of the base portion 21, a tubular barrier portion 25 surrounding the terminal portion 22, and an elastic portion 26 supporting and energizing the barrier portion 25 are provided. Corresponding to each of a plurality of pads 32 provided on the substrate 30, the conductor portion 24 or the conductor portion 24E (an end surface 24b thereof), and a bump 23 connected thereto are provided.

In the socket 20E, the conductor portion 24E routed inside the base portion 21 is provided. The terminal portion 22 is connected to one end surface 24a of such a conductor portion 24E, and the bump 23 is connected to another end surface 24b. Since the conductor portion 24 is routed inside the base portion 21, the bump 23 is provided at a position different from the position directly below the terminal portion 22. According to the socket 20E, even when pitch or layout of the plurality of pads 11 of the semiconductor device 10 and pitch or layout of the plurality of pads 32 of the substrate 30 are different, the semiconductor device 10 and the substrate 30 may be electrically connected via the socket 20E.

Furthermore, in the socket 20E, the barrier portions 25 surrounding the terminal portions 22 are energized by the elastic portions 26 and connected to the semiconductor device 10. The terminal portions 22 are surrounded by the barrier portions 25 until and even after the terminal portions 22 are connected to the pads 11. With this configuration, occurrence of disconnection and a short circuit may be suppressed, and corresponding ones of the pads 11 and the terminal portions 22 may be connected. Even when warpage occurs in the semiconductor device 10 and some of the pads 11 have different gaps from the surface 21a of the base portion 21, occurrence of disconnection and a short circuit may be suppressed, and corresponding ones of the pads 11 and the terminal portions 22 may be connected. According to the socket 20E, the high-quality semiconductor apparatus 1E is achieved in which a connection failure between the semiconductor device 10 and the socket 20E is suppressed.

Note that the terminal portions 22 of the socket 20E move by elastic force generated by bending when being connected to the pads 11 of the semiconductor device 10 while rubbing surfaces of the pads 11, and wipe the surfaces of the pads 11. With this configuration, a coating film, dust, and the like existing on the surfaces of the pads 11 are removed to expose clean surfaces, and the clean surfaces and the terminal portions 22 are connected, which suppresses an increase in resistance between the pads 11 and the terminal portions 22.

As illustrated in FIG. 22, the socket 20E is provided between and connected to the semiconductor device 10 and the substrate 30 to achieve the semiconductor apparatus 1E. For example, according to the example of FIG. 14 described above, the semiconductor apparatus is obtained in which a thermal bonding material 40, the semiconductor device 10, the socket 20E, and the substrate 30 are sandwiched between a cooling part 50 and a plate 60 fixed by fixing parts 70.

Note that, according to the examples of FIGS. 15A to 16B described above, the terminal portions 22, the barrier portions 25, and the elastic portions 26 as illustrated in FIG. 22 may be provided in an outer peripheral portion of the socket 20E corresponding to the outer peripheral portion 13 (FIG. 10A) of the semiconductor device 10, or in a central portion of the socket 20E corresponding to the central portion 12 (FIG. 10A) of the semiconductor device 10.

Furthermore, according to the example of FIG. 13A described above, it is possible not to provide the bumps 23 in the socket 20E before being connected to the substrate 30. Furthermore, according to the example of FIG. 13B described above, a part of the conductor portion 24 and a part of the conductor portion 24E of the socket 20E are protruded from the surface 21b of the base portion 21, and the protruded portion of the conductor portion 24 and the protruded portion of the conductor portions 24E may be used as post electrodes.

Furthermore, according to the examples of FIGS. 17 to 20 described above, terminal portions 82, tubular barrier portions 85 surrounding the terminal portions 82, and elastic portions 86 supporting and energizing the barrier portions 85 may be provided on the side of the surface 21b of the base portion 21. In that case, according to the example of FIG. 20 described above, the terminal portions 82, the barrier portions 85, and the elastic portions 86 provided on the side of the surface 21b of the base portion 21 may be provided in the central portion or the outer peripheral portion of the socket 20E.

Furthermore, according to the example of FIG. 21 described above, a flat plate-shaped one provided with no recess 21c may be used as the base portion 21.

### Sixth Embodiment

The semiconductor apparatuses (semiconductor apparatuses 1, 1A, 1C, 1D, 1E, and the like) using the sockets 20, 20a, 20b, 20A, 20B, 20C, 20Ca, 20D, 20E and the like having the configurations as described in the first to fifth embodiments above may be mounted on various electronic apparatuses. For example, the semiconductor apparatuses using the sockets 20, 20a, 20b, 20A, 20B, 20C, 20Ca, 20D, 20E and the like described above may be mounted on various electronic apparatuses such as a computer (a personal computer, a supercomputer, a server, or the like), a smartphone, a portable telephone, a tablet terminal, a sensor, a camera, an audio apparatus, a measuring apparatus, an inspection apparatus, a manufacturing apparatus, a transmitter, a receiver, and a radar apparatus.

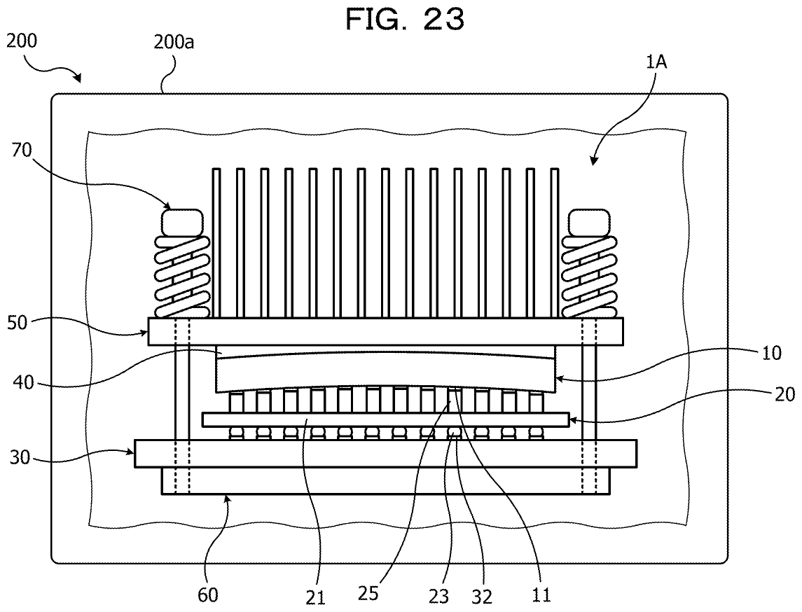

FIG. 23 is a view illustrating an example of an electronic apparatus according to a sixth embodiment. In FIG. 23, the electronic apparatus is schematically illustrated. As illustrated in FIG. 23, for example, the semiconductor apparatus 1A (FIG. 14) using the socket 20 as described in the first embodiment above is mounted (incorporated) inside a housing 200a of various electronic apparatuses 200.

As described above, in the semiconductor apparatus 1A, by application of a load in a direction from a semiconductor device 10 to the socket 20, terminal portions 22 are connected to pads 11, and barrier portions 25 surrounding the terminal portions 22 are energized toward a side of the semiconductor device 10 by elastic portions 26 and connected to the semiconductor device 10 (FIGS. 4 to 9B, and the like). Since the terminal portion 22 is surrounded by the barrier portion 25 connected to the semiconductor device 10, it is avoided that the terminal portion 22 extends by elastic force generated by bending and disengages from the corresponding connected pad 11, and that the terminal portion 22 extends to and is connected to the pad 11 adjacent to the pad 11 and causes a short circuit. Even when the semiconductor device 10 is brought close to the socket 20, the barrier portion 25 is pushed toward a side of the base portion 21 against the energizing force of the elastic portion 26 while maintaining the state of being connected to the semiconductor device 10. Therefore, it is avoided by the elastic force of the terminal portion 22 that, even when the terminal portion 22 is greatly bent, a tip portion 22a slips on a surface of the pad 11 and extends to the outside of the barrier portion 25. Therefore, it is avoided that the terminal portion 22 disengages from the corresponding connected pad 11 and that the terminal portion 22 is connected to the pad 11 adjacent to the pad 11 and causes a short circuit. By using the socket 20 described above, the high-quality semiconductor apparatus 1A is achieved in which a connection failure between the semiconductor device 10 and the socket 20 is suppressed. Such a semiconductor apparatus 1A is mounted to achieve the high-performance electronic apparatus 200.

Here, the electronic apparatus 200 mounting the semiconductor apparatus 1A using the socket 20 has been taken as an example. However, similarly, it is possible to achieve various electronic apparatuses mounting the semiconductor apparatuses using the other sockets 20a, 20b, 20A, 20B, 20C, 20Ca, 20D, 20E and the like.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be under stood that the various changes, substitutions, and alterations could be made hereto without departing from the spirit and scope of the invention.

What is claimed is:

1. A semiconductor apparatus comprising:
a semiconductor device configured to include a first pad; and
a socket provided over a first pad side of the semiconductor device, and configured to include:
a base configured to face the semiconductor device,
a first terminal provided over a semiconductor device side of the base, configured to include flexibility against a load in a direction from the semiconductor device toward the base, and coupled to the first pad,
a first tubular barrier provided over the semiconductor device side and configured to surround the first terminal, and
a first elastic body provided over the semiconductor device side, and configured to support the first tubular barrier and energize the first tubular barrier in a direction from the base toward the semiconductor device.

2. The semiconductor apparatus according to claim 1, wherein
the socket includes a supporter provided over the base and configured to support the first terminal, and
the first tubular barrier and the first elastic body are provided to surround the supporter.

3. The semiconductor apparatus according to claim 1, wherein
the base includes a recess provided over the semiconductor device side, and
the first tubular barrier and the first elastic body are provided in the recess.

4. The semiconductor apparatus according to claim 1, wherein
the semiconductor device includes a central area and an outer peripheral area outside the central area in a plan view, and
the first pad coupled to the first terminal is provided in the outer peripheral area of the semiconductor device.

5. The semiconductor apparatus according to claim 1, wherein the first pad includes a wiping trace formed by the first terminal coupled to the first pad.

6. The semiconductor apparatus according to claim 1, wherein
the semiconductor device includes a second pad, and
the socket includes:
a second terminal provided over the semiconductor device side, configured to include flexibility against the load in the direction from the semiconductor device toward the base, and coupled to the second pad;
a second tubular barrier provided over the semiconductor device side, and configured to surround the second terminal; and
a second elastic body provided over the semiconductor device side, and configured to support the second tubular barrier and energize the second tubular barrier in the direction from the base toward the semiconductor device.

7. The semiconductor apparatus according to claim 6, wherein positions of ends of the first tubular barrier and the second tubular barrier over the semiconductor device side are different from each other relative to a reference position of the base.

8. The semiconductor apparatus according to claim 1, further comprising:
a substrate provided over a side of the socket opposite to the semiconductor device side, and configured to include a third pad; and
a bump provided between the socket and the substrate, and electrically coupled to the first terminal and the third pad.

9. The semiconductor apparatus according to claim 1, further comprising:
a substrate provided over a side of the socket opposite to the semiconductor device side, and configured to include a third pad,
wherein the socket includes:
a third terminal provided over a substrate side of the base, configured to include flexibility against a load in a direction from the substrate toward the base, and coupled to the third pad,
a third tubular barrier provided over the substrate side, and configured to surround the third terminal, and
a third elastic body provided over the substrate side, and configured to support the third tubular barrier and energize the third tubular barrier in a direction from the base toward the substrate.

10. The semiconductor apparatus according to claim 9, wherein the socket includes a conductor configured to penetrate the base and include one end coupled to the first terminal and another end coupled to the third terminal.

11. The semiconductor apparatus according to claim 8, further comprising:
a cooling device provided over a side of the semiconductor device opposite to a side of the socket;
a plate provided over a side of the substrate opposite to the side of the socket; and
a fixing device configured to fix the cooling device to the plate in a state where a load is applied to the socket.

12. A socket comprising:
a base;
a first terminal provided over a first side of the base, and configured to include flexibility against a load in a direction from an outside of the first side toward the base;
a first tubular barrier provided over the first side, and configured to surround the first terminal; and
a first elastic body provided over the first side, and configured to support the first tubular barrier and energize the first tubular barrier in a direction from the base toward the outside of the first side.

13. The socket according to claim 12, further comprising:
a supporter provided over the base, and configured to support the first terminal,
wherein the first tubular barrier and the first elastic body are provided to surround the supporter.

14. The socket according to claim 12, wherein
the base includes a recess provided over the first side, and
the first tubular barrier and the first elastic body are provided in the recess.

15. The socket according to claim 12, wherein
the base includes a central area and an outer peripheral area outside the central area in a plan view, and
the first terminal, the first tubular barrier, and the first elastic body are provided in the outer peripheral area of the base.

16. The socket according to claim 12, further comprising:
a second terminal provided over the first side, and configured to include flexibility against the load in the direction from the outside of the first side toward the base;
a second tubular barrier provided over the first side, and configured to surround the second terminal; and
a second elastic body provided over the first side, and configured to support the second tubular barrier and energize the second barrier in the direction from the base toward the outside of the first side.

17. The socket according to claim 12, further comprising:
a bump provided over a second side of the base opposite to the first side, and electrically coupled to the first terminal.

18. The socket according to claim 12, further comprising:
a third terminal provided over a second side of the base opposite to the first side, and configured to include flexibility against a load in a direction from an outside of the second side toward the base;
a third tubular barrier provided over the second side, and configured to surround the third terminal; and
a third elastic body provided over the second side, and configured to support the third tubular barrier and energize the third tubular barrier in a direction from the base toward the outside of the second side.

19. The socket according to claim 18, further comprising:
a conductor configured to penetrate the base, and include one end coupled to the first terminal and another end coupled to the third terminal.

20. An electronic apparatus comprising:
a semiconductor device configured to include a first pad; and
a socket provided over a first pad side of the semiconductor device, and configured to include:
a base configured to face the semiconductor device,
a first terminal provided over a semiconductor device side of the base, configured to include flexibility against a load in a direction from the semiconductor device toward the base, and coupled to the first pad,
a first tubular barrier provided over the semiconductor device side, and configured to surround the first terminal, and
a first elastic body provided over the semiconductor device side, and configured to support the first tubular barrier and energize the first tubular barrier in a direction from the base toward the semiconductor device.
